(19) United States
(12) Patent Application Publication
(10) Pub. No.: US 2024/0247406 A1
(43) Pub. Date: Jul. 25, 2024

(54) PROCESS FOR RETROGRADE SOLVOTHERMAL CRYSTAL GROWTH AND SINGLE CRYSTAL GROWN THEREBY

(71) Applicant: SLT Technologies, Inc., Los Angeles, CA (US)

(72) Inventors: Drew W. CARDWELL, Rainier, WA (US); Dirk EHRENTRAUT, Camas, WA (US); Mark P. D'EVELYN, Vancouver, WA (US); Rajeev Tirumala PAKALAPATI, Vancouver, WA (US)

(21) Appl. No.: 18/418,141

(22) Filed: Jan. 19, 2024

Related U.S. Application Data
(60) Provisional application No. 63/440,059, filed on Jan. 19, 2023.

(51) Int. Cl. C30B 29/40; C30B 7/10

(52) U.S. Cl. CPC C30B 29/403; C30B 7/105

(57) ABSTRACT

Embodiments of the disclosure include a free-standing crystal, comprising a group III metal and nitrogen. The free-standing crystal may comprise: a wurtzite crystal structure; a growth direction, the growth direction being selected from one of [0 0 0 ±1], {1 0 −1 0}, {1 0 −1 ±1}, or {1 0 −1 ±2}. A first surface having a dislocation density between 1 cm⁻² and 10⁷ cm⁻², the dislocations having an orientation within 30 degrees of the growth direction, and an average impurity concentration of H greater than 10¹⁷ cm⁻³. The free-standing crystal having at least four sets of bands, wherein each set of bands includes a first sub-band and a second sub-band, the first sub-band having a concentration of at least one impurity selected from H, O, Li, Na, K, F, Cl, Br, and I; and each of the at least four sets of bands have portions that are substantially parallel.

### CROSS-REFERENCE TO RELATED APPLICATIONS

This application claims priority to U.S. Provisional Application Ser. No. 63/440,059 filed Jan. 19, 2023, which is herein incorporated by reference in its entirety.

### BACKGROUND

### Field

The present disclosure generally relates to processing of materials in supercritical fluids for growth of crystals useful for forming bulk substrates that can be used to form a variety of optoelectronic, integrated circuit, power device, laser, light emitting diode, photovoltaic, and other related devices.

### Description of Related Art

The present disclosure relates generally to techniques for processing materials in supercritical fluids, such as growth of single crystals. Examples of such crystals include metal oxides, such as MXO₄ crystals, where M represents Al or Ga and X represents P or As, and metal nitrides, such as GaN, AlN, InN, InGaN, AlGaN, and AlInGaN. More specifically, embodiments of the disclosure include techniques for controlling parameters associated with material processing within a capsule or liner disposed within a high-pressure apparatus enclosure. Gallium nitride containing crystalline materials are useful as substrates for manufacture of optoelectronic and electronic devices, such as lasers, light emitting diodes, solar cells, photoelectrochemical water splitting and hydrogen generation devices, photodetectors, integrated circuits, and transistors, among other devices.

Supercritical fluids are used to process a wide variety of materials. A supercritical fluid is often defined as a substance beyond its critical point, i.e., critical temperature and critical pressure. A critical point represents the highest temperature and pressure at which the substance can exist as a vapor and liquid in equilibrium. In certain supercritical fluid applications, the materials being processed are placed inside a pressure vessel or other high-pressure apparatus. In some cases, it is desirable to first place the materials inside a container, liner, or capsule, which in turn is placed inside the high-pressure apparatus. In operation, the high-pressure apparatus provides structural support for the high pressures generated within the container or capsule holding the materials. The container, liner, or capsule provides a closed/sealed environment that is chemically inert and impermeable to solvents, solutes, and gases that may be involved in or generated by the process.

Supercritical fluids provide an especially ideal environment for growth of high-quality crystals, that is, a solvothermal process, in large volumes and low costs. In many cases, supercritical fluids possess the solvating capabilities of a liquid with the transport characteristics of a gas. Thus, on the one hand, supercritical fluids can dissolve significant quantities of a solute for recrystallization. On the other hand, the favorable transport characteristics include a high diffusion coefficient, so that solutes may be transported rapidly through the boundary layer between the bulk of the supercritical fluid and a growing crystal, and also a low viscosity, so that the boundary layer is very thin and small temperature gradients can cause facile self-convection and self-stirring of the reactor. This combination of characteristics enables, for example, the growth of hundreds or thousands of large α-quartz crystals in a single growth run in supercritical water.

In some applications, such as crystal growth, the pressure vessel or capsule also includes a baffle plate that separates the interior into different chambers, e.g., a top half and a bottom half. The baffle plate typically has a plurality of random or regularly spaced holes to enable fluid flow and heat and mass transfer between these different chambers, which hold the different materials being processed along with a supercritical fluid. For example, in typical crystal growth applications, one end of the capsule contains seed crystals and the other end contains nutrient material. In addition to the materials being processed, the capsule contains a solid or liquid that forms the supercritical fluid at elevated temperatures and pressures and, typically, also a mineralizer to increase the solubility of the materials being processed in the supercritical fluid. In some cases, the mineralizer is a mixture of two or more substances [e.g., S. Tysoe, et al., U.S. Pat. No. 7,642,122 (2010)]. In operation, the capsule is heated and pressurized toward or beyond the critical point, thereby causing the solid and/or liquid to transform into the supercritical fluid. In some applications the fluid may remain subcritical, that is, the pressure or temperature may be less than the critical point. However, in all cases of interest here, the fluid is superheated, that is, the temperature is higher than the boiling point of the fluid at atmospheric pressure. The term “supercritical” will be used throughout to mean “superheated”, regardless of whether the pressure and temperature are greater than the critical point, which may not be known for a particular fluid composition with dissolved solutes.

In a number of solvothermal crystal growth systems the solubility is “normal”, that is, the solubility of the substance to be crystallized increases with increasing temperature of the supercritical fluid. In such cases a nutrient material is placed in the hotter end of the growth chamber and seed crystals in the cooler end, with the cooler end above the hotter end so that free convection mixes the fluid. Examples of these systems include α-quartz in supercritical water with NaOH as mineralizer and GaN in supercritical ammonia with acidic mineralizers NH₄Cl, NH₄Br, or NH₄I [D. Tomida, et al., J. Crystal Growth 325, 52 (2011)]. In other cases the solubility is “retrograde”, that is, the solubility decreases with increasing temperature and the relative positions of the nutrient material and seeds within the growth chamber may be reversed. Examples of systems with retrograde solubility include AlPO₄ (berlinite) in supercritical water with HCl as mineralizer [E. D. Kolb and R. A. Laudise, U.S. Pat. No. 4,300,979 (1981)] and AlN in supercritical ammonia with basic mineralizer KNH₂ [D. Peters, J. Crystal Growth 104, 411 (1990)]. GaN in supercritical ammonia with basic mineralizer KNH₂ similarly exhibits retrograde solubility [R. Dwilinski, et al., J. Crystal Growth 310, 3911 (2008)]. GaN in supercritical ammonia with acidic mineralizer NH₄F also exhibits retrograde solubility [M. D'Evelyn, et al., U.S. Pat. No. 7,078,731 (2006)], in contrast to the other acidic mineralizers mentioned above.

A challenge associated with crystal growth in a retrograde solubility system is that the hottest points in the growth chamber are typically on the wall surrounding the seed crystals, with the consequence that adventitious nuclei may form on the walls and grow preferentially with respect to the seed crystals. Wall crystallization may decrease the material deposition efficiency of the process, that is, the fraction of dissolved nutrient material that crystallizes on the seed crystals, and may also interfere with the growth of crystals proximate to the walls. The severity of this wall deposition problem may be sensitive to the temperature distribution within the crystal growth zone and the temperature difference between the nutrient zone and the crystal growth zone. Material deposition efficiency is an important factor in economically forming free-standing crystals.

Therefore, what is needed are improved apparatus and methods for improving the crystal growth process yield and formed crystal properties by controlling the internal temperature distribution and time dependence during solvothermal crystal growth where the solubility is retrograde, in order to reduce adventitious wall deposition on surfaces in the growth zone and improve the crystal growth process.

### SUMMARY

According to the present disclosure, techniques related to processing of materials for growth of crystals are provided. More particularly, the present disclosure provides apparatus and methods for heating of seed crystals suitable for use in conjunction with a high-pressure vessel for crystal growth of a material having a retrograde solubility in a supercritical fluid, including crystal growth of a group III metal nitride crystal by an ammonobasic or ammonoacidic technique, but there can be others. In other embodiments, the present disclosure provides methods suitable for synthesis of crystalline nitride materials, but it would be recognized that other crystals and materials can also be processed. Such crystals and materials include, but are not limited to, GaN, AlN, InN, InGaN, AlGaN, and AlInGaN, BN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

Embodiments of the disclosure include a free-standing crystal, comprising a group III metal and nitrogen. The free-standing crystal may comprise: a wurtzite crystal structure; a growth direction, the growth direction being selected from one of [0 0 0 ±1], {1 0 −1 0}, {1 0 −1 ±1}, or {1 0 −1 ±2}; a first surface having a maximum dimension in a first direction; and a second surface on the opposite side of the crystal from the first surface. The second surface is separated from the first surface in a second direction that is orthogonal to the first direction, and the second direction being within 10 degrees of the growth direction. The first surface is characterized by a dislocation density between 1 cm⁻² and 10⁷ cm⁻², at least 50% of the dislocations having an orientation within 30 degrees of the growth direction, an average impurity concentration of H greater than 10¹⁷ cm⁻³, and an average impurity concentration of at least one of Li, Na, K, F, Cl, Br, and I greater than 10¹⁵ cm⁻³, as quantified by calibrated secondary ion mass spectrometry. The free-standing crystal is characterized by at least four sets of bands, wherein each set of bands includes a first sub-band and a second sub-band, the first sub-band having a concentration of at least one impurity selected from H, O, Li, Na, K, F, Cl, Br, and I that is higher, by a factor between about 1.05 and about 100, than a concentration of the same impurity within the second sub-band; and each of the at least four sets of bands have at least portions that are substantially parallel, a thickness of each of the at least four sets of bands in the growth direction being between about 0.1 micrometer and about 500 micrometers.

Embodiments of the disclosure include a method for forming a group III metal nitride boule or wafer, comprising: forming a single crystalline layer at least one millimeter thick on a surface of at least one seed crystal, wherein forming the single crystalline layer comprises: heating a sealable container to a temperature above about 200 degrees Celsius, wherein an interior region of the sealable container comprises the at least one seed crystal, a polycrystalline group III metal nitride nutrient material, a mineralizer material, and ammonia, a first region of the interior region comprises the polycrystalline group III metal nitride nutrient, a second region of the interior region comprises the at least one seed crystal, and the heating of the sealable container causes a pressure within interior region of the sealable container to be above about 50 megapascals. Sequentially adjusting a temperature difference between the first region and the second region, wherein the temperature difference has a magnitude between about 1 degree Celsius and about 100 degrees Celsius and a positive or a negative sign, and the magnitude and/or sign of the sequentially adjusted temperature difference is performed at least once during the formation of the single crystalline layer. The thickness of the formed single crystal layer can be measured in a first growth direction, and at least 50% of dislocations formed in the formed single crystal layer have an orientation within 30 degrees of the first growth direction. The thickness of the formed single crystal layer can be measured in a first growth direction and the formed single crystal layer comprises an oxygen gradient that decreases in the first growth direction extending from the surface of the at least one seed crystal. In some embodiments the process of forming the single crystalline layer further comprises: sequentially depositing a plurality of sub-bands at a material efficiency greater than 60%, wherein material efficiency is defined as a weight gain of group III metal nitride material deposited on the at least one seed crystal divided by a weight gain of group III metal material deposited on all surfaces within the second region.

Embodiments of the disclosure include a method for forming a group III metal nitride boule or wafer. The method includes placing at least one seed crystal, a polycrystalline group III metal nitride nutrient material, a mineralizer material, and ammonia within a sealable container. Then heating the sealable container to a temperature above about 200 degrees Celsius such that the a pressure within the sealable container is above about 50 megapascals; and providing a temperature difference between a first region of the sealable container containing the polycrystalline group III metal nitride nutrient material and a second region of the sealable container containing the at least one seed crystal, the temperature difference between the first region of the sealable container and the second region of the sealable container having a magnitude between about 1 degree Celsius and about 100 degrees Celsius and having a sign and magnitude that enables etching of the polycrystalline group III metal nitride nutrient material and single crystal growth on the at least one seed crystal; periodically sequentially reducing the magnitude and/or reversing the sign of the temperature difference between the first region of the sealable container and the second region of the sealable container so as to etch adventitious group III metal nitride nuclei that form on a surface within the second region; and depositing a single crystalline layer at least one millimeter thick on a surface of the at least one seed crystal, wherein a material efficiency, defined as the a weight gain of group III metal nitride material deposited on the at least one seed crystal divided by the a weight gain of group III metal material deposited on all surfaces within the second region, is greater than 60%.

The present disclosure achieves these benefits and others in the context of known process technology. However, a further understanding of the nature and advantages of the present disclosure may be realized by reference to the latter portions of the specification and attached drawings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIGS. 1A, 1B, and 1C are a schematic diagram showing heat fluxes into a growth chamber for crystals by a solvothermal process with retrograde solubility and associated wall deposition.

FIG. 2 is a schematic diagram showing a pressure vessel apparatus according to an embodiment of the current disclosure.

FIG. 3 is a schematic diagram showing an internally-heated pressure vessel apparatus according to an embodiment of the current disclosure.

FIG. 4 is a schematic diagram showing a temperature-versus-time profile for a solvothermal process according to a prior art embodiment.

FIG. 5 is a schematic diagram showing an expanded view of a temperature-versus-time profile for a solvothermal process according to an embodiment of the current disclosure.

FIG. 6 is a schematic diagram showing an expanded view of a temperature-versus-time profile for a solvothermal process according to another embodiment of the current disclosure.

FIG. 7 is a schematic diagram showing an expanded view of a temperature-versus-time profile for a solvothermal process according to yet another embodiment of the current disclosure.

FIGS. 8A, 8B, and 9 are schematic diagrams showing an expanded view of a temperature-versus-time profile for a solvothermal process with multiple azimuthal hot zone sectors according to embodiments of the current disclosure.

FIG. 10 is a schematic diagram showing a simplified flow diagram of a method of processing a material within a supercritical fluid, according to an embodiment of the present disclosure.

FIGS. 11, 12, 13. 14, and 15 are schematic diagrams showing impurity concentrations as a function of depth within a crystal according to certain embodiments of the present disclosure.

FIG. 16 is a schematic diagram showing methods for preparing wafers by slicing a grown crystal, according to certain embodiments of the present disclosure.

FIGS. 17, 18A, 18B and 18C are schematic diagrams showing wafers prepared according to certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

According to the present disclosure, techniques related to processing of materials for growth of crystals are provided. More particularly, the present disclosure provides improved heater designs and a thermal control system suitable for use in conjunction with a high-pressure vessel for crystal growth of a material having a retrograde solubility in a supercritical fluid, including crystal growth of a group III metal nitride crystal by an ammonobasic or ammonoacidic technique, but there can be others. In other embodiments, the present disclosure provides methods suitable for synthesis of crystalline nitride materials, but it would be recognized that other crystals and materials can also be processed. Such crystals and materials include, but are not limited to, GaN, AlN, InN, InGaN, AlGaN, and AIInGaN, BN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

The disclosure includes embodiments that may relate to an apparatus for making a composition. The disclosure includes embodiments that may relate to a method of making and/or using the composition.

Approximating language, as used herein throughout the specification and claims, may be applied to modify any quantitative representation that could permissibly vary without resulting in a change in the basic function to which it may be related. Accordingly, a value modified by a term such as “about” may be not to be limited to the precise value specified. In at least one instance, the variance indicated by the term about may be determined with reference to the precision of the measuring instrumentation. Similarly, “free” may be combined with a term; and, may include an insubstantial number, or a trace amount, while still being considered free of the modified term unless explicitly stated otherwise.

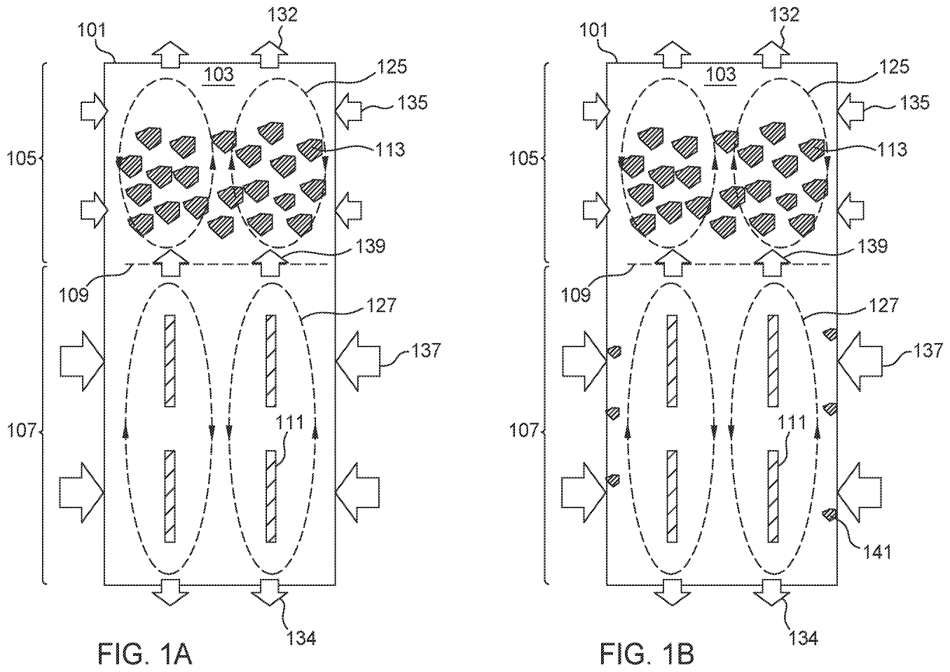

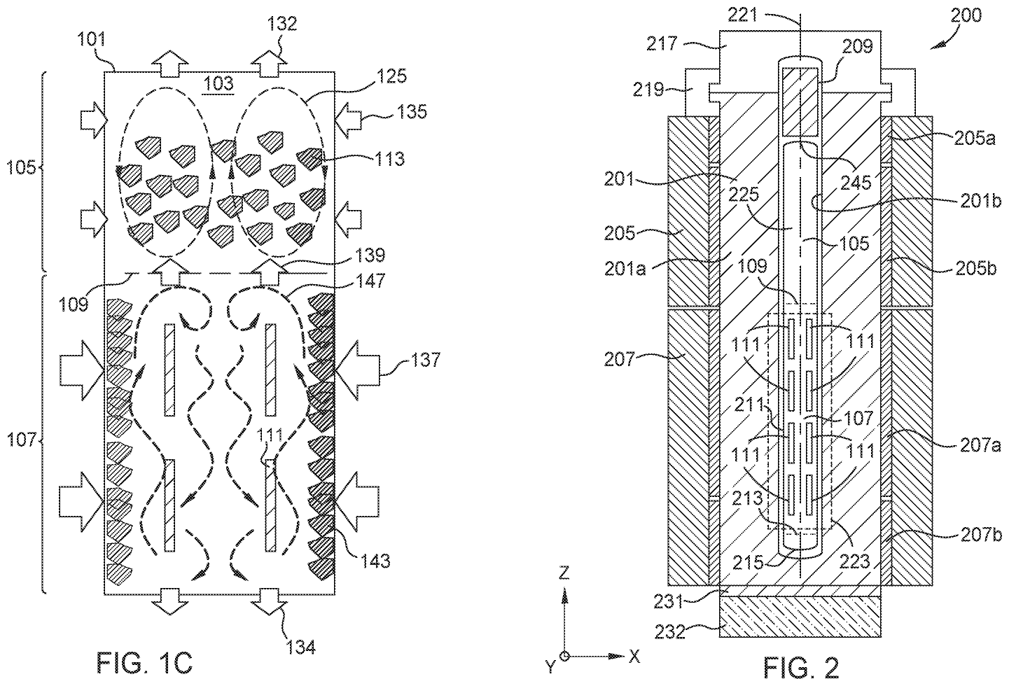

The technical challenge addressed by the present disclosure is illustrated schematically in FIGS. 1A-1C. Referring to FIG. 1A, a growth chamber 101 may include or consist of the inner surface of an autoclave or pressure vessel, the inner surface of liner within an autoclave, the inner surface of a capsule within an autoclave or within an internally-heated high-pressure apparatus, or the like. As used here, an autoclave refers to a thick-walled pressure vessel for processing materials at elevated temperature and pressures. An internally-heated high-pressure apparatus, which is also capable of processing materials at elevated temperature and pressure, may also be considered a pressure vessel, although its construction may be quite different than that of a conventional pressure vessel. The autoclave, pressure vessel, or internally-heated high-pressure apparatus will normally have a cylindrical shape and be vertically oriented. The interior volume 103 is filled with a supercritical fluid, such as ammonia or water, in which a mineralizer is dissolved. Growth chamber 101 may be divided into an upper chamber 105 and a lower chamber 107 by a baffle 109. Baffle 109 may include one or more disks, conical portions, spheroidal portions, or the like, with one or more perforations and annular gaps with respect to growth chamber 101, to allow for restricted fluid motion through the baffle. One or more seed crystals 111 are suspended within lower chamber 107 from furniture (not shown), and one or more chunks of polycrystalline nutrient 113 is placed within upper chamber 105. In certain embodiments, polycrystalline nutrient 113 is placed within one or more baskets (not shown). This configuration is suitable for crystal growth in a system with retrograde solubility, with etching of polycrystalline nutrient 113 occurring in upper chamber 105 and growth of crystalline material on seed crystals 111 occurring in lower chamber 107.

Growth chamber 101 may be heated to a temperature distribution suitable for crystal growth by means of one or more electric heaters (not shown). An exemplary (prior art) heater suitable for an autoclave is described by Dwilinski (U.S. Pat. No. 6,656,615) and includes cylindrical, separately controlled hot zones surrounding upper chamber 105 and lower chamber 107. An exemplary (prior art) heater suitable for an internally heated high pressure apparatus is described by Giddings (U.S. Pat. No. 7,705,276) and includes cylindrical, separately controlled hot zones surrounding upper chamber 105 and lower chamber 107 and placed within a cylindrical high strength enclosure. Conditions suitable for crystal growth are achieved by heating lower chamber 107 to a temperature that is higher than that of upper chamber 105, causing growth zone free convection 127 to occur within lower chamber 107 and nutrient zone free convection 125 to occur within upper chamber 105. The temperature difference between lower chamber 107 and upper chamber 105 may be between about 1 degree Celsius and about 100 degrees Celsius, between about 3 degrees Celsius and about 30 degrees Celsius, or between about 5 degrees Celsius and about 20 degrees Celsius. Under steady-state growth conditions the temperature distribution within growth chamber 101 is quasi-steady state and the rate of deposition of crystalline material in lower chamber 107 is equal to the rate of etching of polycrystalline nutrient in upper chamber 105. Therefore, under steady-state conditions the net heat flux through the boundary of growth chamber 101 is zero or, put differently, heat flux inward through certain portions of the boundary of growth chamber 101 is counter-balanced by heat flow outward through other portions of the boundary of growth chamber 101. While the precise details of the heat flux distribution will depend on the precise power distribution applied to the heater, in general the growth zone heat flux 137, through the cylindrical perimeter of lower chamber 107, will flow inward, so as to enable lower chamber 107 to be hotter than upper chamber 105. For the same reason, baffle heat flux 139 will flow upward, from lower chamber 107 to upper chamber 105. In the simple case that the heater is cylindrical, the bottom heat flux 134 and the top heat flux 132, through the bottom and top portions of the boundary of growth chamber 101, respectively, will flow outward. Depending on details, nutrient zone heat flux 135, through the cylindrical perimeter of upper chamber 105, may be outward or inward.

As a consequence of the heat fluxes shown schematically in FIG. 1A, the hottest surfaces within growth chamber 101 will typically be on the perimeter of lower chamber 107. For a system with retrograde solubility, the thermodynamic driving force for deposition will be maximum on these surfaces, and therefore nuclei 141 may form on these surfaces, as shown schematically in FIG. 1B. Furthermore, since the surfaces where nuclei 141 form are the hottest surfaces within growth chamber 101, nuclei 141 will grow faster than seed crystals 111. As the crystal growth process continues, therefore, nuclei 141 may coalesce into a continuous polycrystalline film 143, as shown schematically in FIG. 1C. The roughness and thickness of continuous polycrystalline film 143 may cause modification of growth zone free convection 147. Growth on seed crystals 111 may be impeded due both to competition with continuous polycrystalline film 143 for dissolved nutrient material and to the perturbed growth zone free convection 147. In extreme cases, when the temperature difference between continuous polycrystalline film 143 and seed crystals 111 becomes large and the flux of dissolved nutrient from upper chamber 105 to lower chamber 107 is inhibited, for example, by depletion of polycrystalline nutrient 113 or clogging of one or more of holes and annular gaps within baffle 109, seed crystals can be etched rather than growing while the continuous polycrystalline film 143 continues to grow.

An additional consequence of a non-optimum temperature distribution associated with excessive temperatures in the side walls of the lower chamber 107 is that the bottom portion of lower chamber 107 may have a temperature minimum, which may give rise to stagnant fluid flow due to the suppression or disruption of the convective fluid flow currents and thus a non-optimum flow of fluid over seed crystals 111.

FIG. 2 is a simplified diagram of a high-pressure apparatus according to an embodiment of the present disclosure. This diagram is merely an example, which should not unduly limit the scope of the claims herein. One of ordinary skill in the art would recognize other variations, modifications, and alternatives. As shown, the present disclosure provides an apparatus for high pressure crystal or material processing, e.g., GaN, AlN, InN, InGaN, AlGaN, AlInGaN, and BN. Other processing methods include hydrothermal crystal growth of oxides and other crystalline materials, hydrothermal or ammonothermal syntheses, and hydrothermal decomposition, and others. Of course, there can be other variations, modifications, and alternatives.

Referring to FIG. 2, a high-pressure apparatus and related methods for processing materials in supercritical fluids are disclosed. In certain embodiments, the improved heater is employed as a component of an autoclave. The autoclave may be capable of processing a material in a fluid at a pressure above about 5 MPa and below about 500 MPa, below about 400 MPa, below about 300 MPa, below about 200 MPa, or below about 100 MPa, or in a range between about 5 MPa and 100 MPa, such as about 50 MPa, at temperatures between about 50 degrees Celsius and about 900 degrees Celsius, such as between about 100 degrees Celsius and about 600 degrees Celsius, between about 150 degrees Celsius and about 500 degrees Celsius, or between about 200 degrees Celsius and about 400 degrees Celsius. Referring to FIG. 2, autoclave 200 includes an autoclave body 201 that includes a wall 201a that includes an inner surface 201b. The upper portion of autoclave body 201 may be surrounded by at least one upper heater 205 and the lower portion of autoclave body may be surrounded by at least one lower heater 207, each of which may include insulation. Upper heater 205 may include one, two, or more independently-controllable hot zones, for example, top tail zone 205a and top main zone 205b. Lower heater 207 may include one, two, or more independently-controllable hot zones, for example, bottom main zone 207a and bottom tail zone 207b. Upper heater 205 and lower heater 207 may be physically joined into a unitary component but are typically independently controllable. In certain embodiments, a liner 211 is placed within a cavity of autoclave body 201. The inner surface of liner 211, or the inner surface 201b of autoclave body 201, if liner 211 is not present, can be used to form a cylindrical chamber 225 in which the methods for processing materials in supercritical fluids can be performed. The cylindrical chamber 225, which can also be referred to as a growth chamber, includes a central axis 221 that extends through the upper and lower portions of the autoclave body 201. Liner 211 may be formed from or may include one or more of platinum, palladium, iridium, a Pt/Ir alloy, gold, or silver. In one example, the liner 211 may include a pure solid silver or solid silver alloy sheet of material. Liner 211 may also include or be formed from one or more of titanium, rhenium, copper, iron, nickel, stainless steel, zirconium, tantalum, molybdenum, niobium, alloys thereof, and the like. A baffle 109 may be positioned within liner 211, if it is present, and/or the interior of autoclave body 201. Baffle 109 may include one or more disks, conical portions, spheroidal portions, or the like, with one or more perforations and annular gaps with respect to the inner diameter of liner 211, if present, to allow for restricted fluid motion through the baffle. In certain embodiments, a bottom baffle 213 may be provided within a certain distance of the bottom surface 215 of liner 211, if the latter is present, or of the bottom inner surface of the interior of autoclave body 201. Baffle 109 and bottom baffle 213 may be formed from or may include one or more of platinum, palladium, iridium, a Pt/Ir alloy, gold, silver, titanium, rhenium, copper, iron, nickel, stainless steel, zirconium, tantalum, molybdenum, niobium, alloys thereof, and the like. Bottom baffle 213 may have the form of a flat disk. Bottom baffle 213 may include one or more holes, which may have a diameter between about 1 millimeter and about 25 millimeters. An annular gap may be present between the outer diameter of bottom baffle 213 and the inner diameter of liner 211, if the latter is present, or of the inner diameter of autoclave body 201, if liner 211 is not present, between about 0.5 millimeter and about 25 millimeters.

A cylindrical chamber, such as cylindrical chamber 225, will include a plurality of seed mounts (not shown) on which the seed crystals 111, illustrated in FIG. 2, are disposed in a spaced-apart vertical array of seed crystals 111 that extend in a first direction (i.e., Z-direction) from a bottom surface of the interior region of the cylindrical chamber 225. In other words, the seed mounts are configured in a spaced-apart vertical array 223 to support the seed crystals during processing. The plurality of crystal-supporting seed mounts may be positioned within a lateral array of seed mounts at each level of the vertical array 223, and be aligned in an orthogonal relationship to the vertical array 223 that extends in a radial direction.

In certain embodiments, autoclave 200 further includes autoclave cap 217 and closure fixture 219, as shown schematically, plus a gasket (not shown). The configuration shown in FIG. 2 is a schematic representation of a Grayloc™ seal. In other embodiments, autoclave 200 includes one or more of an unsupported Bridgman seal, an o-ring seal, a c-ring seal, a confined gasket seal, a bolted closure, an AE™ closure, an EZE-Seal™, a Keuntzel closure, a ZipperClave™ closure, a threadless pin closure, or a Gasche™ gasket seal. In certain embodiments, autoclave 200 further includes a cap, closure fixture, and seal on the lower end, in addition to the cap, closure fixture, and seal on the upper end.

Autoclave body 201, autoclave cap 217, and closure fixture 219 may each be fabricated from a material selected from a group consisting of steel, low-carbon steel, SA723 steel, SA266 carbon steel, 4340 steel, A-286 steel, iron based superalloy, nickel based superalloy, cobalt based superalloy, Inconel 718, Rene 41, 304 stainless steel, 310 stainless steel, 316 stainless steel, 340 stainless steel, 410 stainless steel, and 17-4 precipitation hardened stainless steel, zirconium and its alloys, titanium and its alloys, and other materials commonly known as Monel®, Inconel®, Hastelloy®, Udimet® 500, Stellite®, Rene® 41, and Rene© 88. One or more of the components comprising autoclave body 201, autoclave cap 217, and closure fixture 219 may undergo a heat treatment operation. In certain embodiments, autoclave body 201 includes a demountable seal at the bottom as well as at the top.

Autoclave 200 may further comprise a bottom end heater 231 that is thermally coupled to the bottom portion of autoclave body 201 and may include thermal insulation 232. Bottom end heater 231 generates a power distribution that is approximately azimuthally uniform about the central axis of autoclave body 201. The power level in bottom end heater 231, relative to the power level in lower heater 207 and upper heater 205, along with the radial dependence of the power density within bottom end heater 231, may be chosen so as to maintain a temperature distribution along bottom surface 215 that is uniform to within 10 degrees Celsius, within 5 degrees Celsius, within 2 degrees Celsius, within 1 degree Celsius, within 0.5 degree Celsius, or within 0.2 degree Celsius. In certain embodiments, the power level in bottom end heater 231, relative to the power level in lower heater 207 and upper heater 205, along with the radial dependence of the power density within bottom end heater 231, is chosen so as to maintain an average temperature of bottom surface 215 that is equal to the average temperature within a specified height range of the inner surface of liner 211, or of the inner surface of autoclave body 201 if liner 211 is not present, to within 20 degrees Celsius, within 10 degrees Celsius, within 5 degrees Celsius, within 2 degrees Celsius, or within 1 degree Celsius. The specified height range is measured with respect to the bottom surface 215. In certain embodiments the specified height is approximately 1 centimeter, 5 centimeters, 10 centimeters, 20 centimeters, or 25 centimeters. In certain embodiments, the bottom end heater 231 is configured with at least two or at least three independently-controllable hot zones.

In certain embodiments, autoclave 200 further includes a top insulator/heater 209. In certain embodiments, top insulator/heater 209 includes or consists of a load-bearing thermal insulator, for example, zirconia or another ceramic material with a low thermal conductivity. In certain embodiments, top insulator/heater also has capability to generate heat, for example, by means of electrical connections through autoclave cap 217. In certain embodiments, top insulator/heater 209 includes one or more of a cartridge heater, a cable heater, a disk heater, or the like. The dimensions of top insulator/heater 209 and its power level, if present, along with the power levels in lower heater 207 and upper heater 205, along with the radial dependence of the power density within top insulator/heater 209, may be chosen so as to maintain a temperature distribution along top surface 245 that is uniform to within 10 degrees Celsius, within 5 degrees Celsius, within 2 degrees Celsius, or within 1 degree Celsius. In addition, the dimensions of top insulator/heater 209 and the power levels of upper heater 205 and lower heater 207 may be chosen to maintain top surface 245 at an average temperature that is equal to the average temperature within a specified height, measured with respect to top surface 245, of the inner surface of liner 211, or of the inner surface of autoclave body 201, if liner 211 is not present, to within 20 degrees Celsius, within 10 degrees Celsius, within 5 degrees Celsius, within 2 degrees Celsius, or within 1 degree Celsius. In certain embodiments the specified height is approximately 1 centimeter, 5 centimeters, 10 centimeters, 20 centimeters, or 25 centimeters. In certain embodiments, the top insulator/heater 209 is configured with at least two or at least three independently-controllable hot zones.

Further details of the fabrication and properties of bottom end heater 131 and of top insulator/heater 209 are described in U.S. patent application Ser. No. 17/963,004, which is hereby incorporated by reference in its entirety.

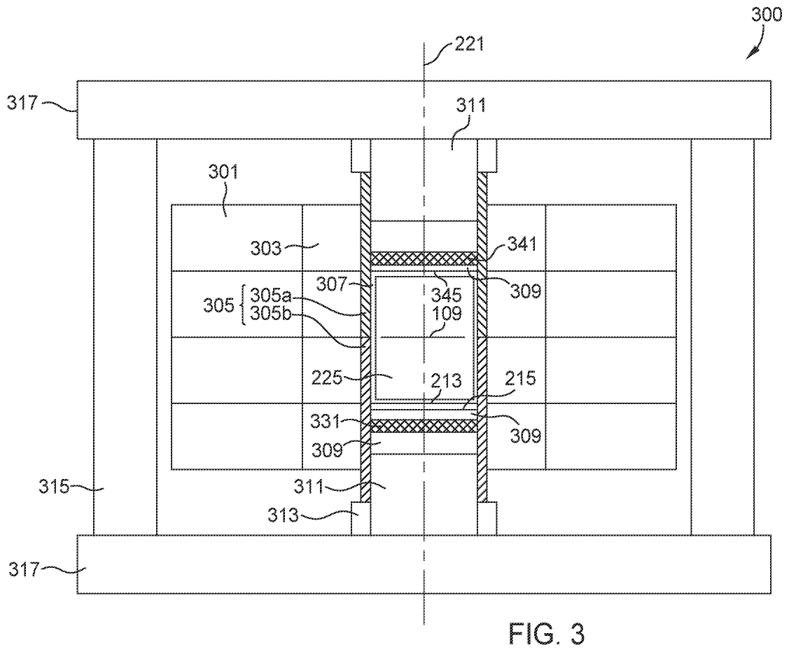

FIG. 3 is a simplified diagram of an internally-heated high-pressure apparatus according to an embodiment of the present disclosure. This diagram is merely an example, which should not unduly limit the scope of the claims herein. One of ordinary skill in the art would recognize other variations, modifications, and alternatives. As shown, the present disclosure provides an apparatus for high pressure crystal or material processing, e.g., GaN, AlN, InN, InGaN, AlGaN, AlInGaN, and BN. Other processing methods include hydrothermal crystal growth of oxides and other crystalline materials, hydrothermal or ammonothermal syntheses, and hydrothermal decomposition, and others. Of course, there can be other variations, modifications, and alternatives.

Referring to FIG. 3, a high-pressure apparatus and related methods for processing supercritical fluids are disclosed. In certain embodiments, the improved heater is employed as a component of an internally-heated high-pressure apparatus. The apparatus provides adequate containment in all directions which, for a typical cylindrical vessel, can be classified as radial and axial. Furthermore, depending on the specifics of the design parameters, the apparatus is capable of operating at temperatures between 200 degrees Celsius and 1500 degrees Celsius, pressures between about 5 MPa and about 2000 MPa, and for whatever length of time is necessary to grow satisfactory bulk crystals, for example, between about 1 hour and about 180 days. The internally-heated high-pressure apparatus 300 may include a stack of one or more ring assemblies to provide radial confinement, comprising a high strength enclosure ring 301 and a ceramic ring 303. The stack may include greater than 2, greater than 5, greater than 10, greater than 20, greater than 30, greater than 50, or greater than 100 ring assemblies. The stack surrounds heater or heating member 305 and capsule 307 and may be supported mechanically by at least one support plate (not shown). The stack may provide radial confinement for pressure generated within capsule 307 and transmitted outward through heater 305. Heater 305 includes an upper heater 305a and a lower heater 305b. Each of upper heater 305a and lower heater 305b may include one, two, or more independently-controllable hot zones. Upper heater 305a and lower heater 305b may be physically joined into a unitary component but are typically independently controllable. The interior of heater 305 may define a processing chamber, into which capsule 307 may be placed. In the case that the ring assemblies in the die stack are comprised of high strength enclosure ring 301 and ceramic ring 303, there may be an interference fit between the two members in each ring assembly. Means for external cooling of the one or more ring assemblies or radial restraints may be provided. In certain embodiments, capsule 307 includes an inner capsule member and an outer capsule member (not shown).

Axial confinement of pressure generated within capsule 307 may be provided by end plugs 311, crown members 317, and tie rods or tie rod fasteners 315. End plugs 311 may comprise zirconium oxide or zirconia. End plugs 311 may be surrounded by end plug jackets 313. End plug jackets may provide mechanical support and/or radial confinement for end plugs 311. End plug jackets 313 may also provide mechanical support and/or axial confinement for heater 305. End plug jackets 313 may comprise steel, stainless steel, an iron-based alloy, a nickel-based alloy, or the like. In certain embodiments, tie rod fasteners 315 are arranged in a configuration that provides axial loading of two or more ring assemblies. Further details are provided in U.S. Pat. Nos. 9,724,666 and 10,174,438, which are hereby incorporated by reference in their entirety.

Crown members 317 and tie rod fasteners 315 may comprise a material selected from a group consisting of steel, low-carbon steel, SA723 steel, SA266 carbon steel, 4340 steel, A-286 steel, iron based superalloy, 304 stainless steel, 310 stainless steel, 316 stainless steel, 340 stainless steel, 410 stainless steel, 17-4 precipitation hardened stainless steel, zirconium and its alloys, titanium and its alloys, and other materials commonly known as Monel®, Inconel®, Hastelloy®, Udimet® 500, Stellite®, Rene® 41, and Rene® 88.

The internally-heated high-pressure apparatus 300 may include a pressure transmission medium 309 proximate to the axial ends of capsule 307 and to end plugs 311 according to a specific embodiment. Pressure transmission medium 309 may include multiple components, for example, one or more disks. The pressure transmission medium may comprise sodium chloride, other salts, or phyllosilicate minerals such as aluminum silicate hydroxide or pyrophyllite, or other materials, according to a specific embodiment.

Capsule 307, which may also be referred to as a process capsule, may be formed from or may include one or more of platinum, palladium, iridium, a Pt/Ir alloy, gold, or silver. In one example, the capsule 307 may include a pure solid silver or solid silver alloy sheet of material. Capsule 307 may also include or be formed from one or more of titanium, rhenium, copper, iron, nickel, stainless steel, zirconium, tantalum, molybdenum, niobium, alloys thereof, and the like. Capsule 307 may further include an outer, support capsule, to provide additional mechanical strength. The support capsule may include or consist of one or more of steel, stainless steel, carbon steel, iron-based alloy or superalloy, nickel, nickel-based alloy or superalloy, Inconel® nickel-chromium iron alloy, Hastelloy® nickel-molybdenum-chromium alloy, Ren6® 41 nickel-based alloy, Waspalloy® nickel-based alloy, Mar-M 247® polycrystalline cast nickel-based alloy, Monel® nickel-copper alloy, Stellite® cobalt-chromium alloy, copper, copper-based alloy, zirconium, niobium, molybdenum, tantalum, tungsten, rhenium, platinum, platinum-based alloy, palladium, iridium, ruthenium, rhodium, osmium, titanium, vanadium, chromium, gold, silver, or aluminum, combinations thereof, and the like. Further details about capsule 307 are described in U.S. Pat. No. 10,029,955, which is hereby incorporated by reference in its entirety.

A baffle 109 may be positioned within capsule 307, dividing the internal volume of capsule 307 into an upper chamber and a lower chamber. Baffle 109 may include one or more disks, conical portions, spheroidal portions, or the like, with one or more perforations and annular gaps with respect to the inner diameter of capsule 307 to allow for restricted fluid motion through the baffle. Baffle 109 may be formed from or may include one or more of platinum, palladium, iridium, a Pt/Ir alloy, gold, silver, titanium, rhenium, copper, iron, nickel, stainless steel, zirconium, tantalum, molybdenum, niobium, alloys thereof, and the like. In one example, the baffle 109 may include a pure solid silver or solid silver alloy sheet of material.

The internally-heated high-pressure apparatus 300 may further comprise a bottom end heater 331 and/or a top end heater 341 that are thermally coupled to the bottom portion and the top portion of capsule 307, respectively. Bottom end heater 331 generates a power distribution that is approximately azimuthally uniform about the axis of heater 305 and the relative power level in bottom end heater 331, relative to the power level in lower heater 305b and upper heater 305a, along with the radial dependence of the power density within bottom end heater 331, is chosen so as to maintain a temperature distribution along bottom surface 215 or, alternatively, along bottom baffle 213, that is uniform within 10 degrees Celsius, within 5 degrees Celsius, within 2 degrees Celsius, or within 1 degree Celsius. In certain embodiments, the relative power level in bottom end heater 331, relative to the power level in lower heater 305b and upper heater 305a, along with the radial dependence of the power density within bottom end heater 331, is chosen so as to maintain an average temperature of bottom surface 215 or, alternatively, of bottom baffle 213, that is equal to the average temperature within a specified height, measured with respect to bottom surface 215, of the inner surface of capsule 307, to within 20 degrees Celsius, within 10 degrees Celsius, within 5 degrees Celsius, within 2 degrees Celsius, or within 1 degree Celsius. In certain embodiments the specified height is approximately 1 centimeter, 5 centimeters, 10 centimeters, 20 centimeters, or 25 centimeters. Top end heater 341, if present, generates a power distribution that is approximately azimuthally uniform about the axis of heater 305 and the relative power level in top end heater 341, relative to the power level in lower heater 305b and upper heater 305a, along with the radial dependence of the power density within top end heater 341, is chosen so as to maintain a temperature distribution along top surface 345 that is uniform within 10 degrees Celsius, within 5 degrees Celsius, within 2 degrees Celsius, or within 1 degree Celsius. In certain embodiments, the relative power level in top end heater 341, relative to the power level in lower heater 305b and upper heater 305a, along with the radial dependence of the power density within top end heater 341, is chosen so as to maintain an average temperature of top surface 345 that is equal to the average temperature within a specified height range, measured with respect to top surface 345, of the inner surface of capsule 307, to within 20 degrees Celsius, within 10 degrees Celsius, within 5 degrees Celsius, within 2 degrees Celsius, or within 1 degree Celsius.

Referring again to FIGS. 1B, because of the thermodynamic driving force for preferential deposition on the walls, as compared to the seed crystals, small nuclei that form on the walls will subsequently grow faster than the seed crystals. It is the primary focus of the present disclosure to etch away these wall nuclei before they can coalesce and outgrow the seed crystals.

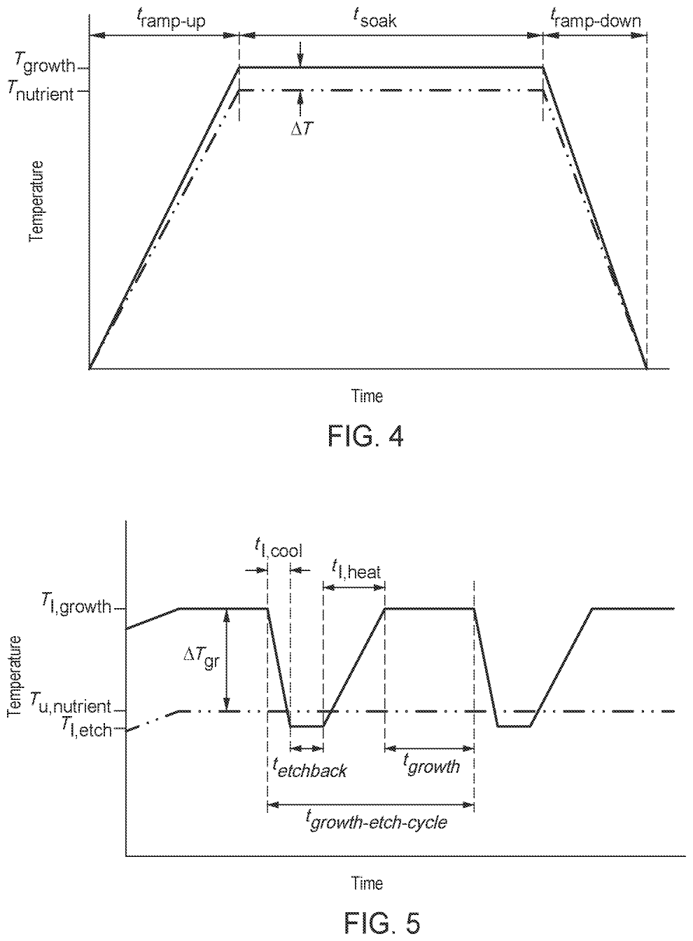

FIG. 4 shows, schematically, a temperature profile for a conventional solvothermal crystal growth process where the solubility is retrograde. In this temperature-time profile, an average temperature of upper chamber 105 is indicated by dot-dashed lines, and an average temperature of lower chamber 107 is indicated by solid lines. Upper chamber 105, containing nutrient 113, may be heated from room temperature to a target nutrient temperature, Tₙᵤₜᵣᵢₑₙₜ, over a period of time tᵣₐₘₚ₋ᵤₚ. Lower chamber 107, containing seed crystals 111, may similarly be heated from room temperature to a target growth temperature, T_{growth}, over a period of time tᵣₐₘₚ₋ᵤₚ. For GaN growth, T_{growth} may be in a range between about 400 degrees Celsius and about 1000 degrees Celsius, or between about 450 degrees Celsius and about 800 degrees Celsius, and a temperature difference ΔT=T_{growth}−Tₙᵤₜᵣᵢₑₙₜ, may be between about 1 degree Celsius and about 100 degrees Celsius, between about 2 degrees Celsius and about 50 degrees Celsius, or between about 3 degrees Celsius and about 25 degrees Celsius. For growth of other nitrides, such as AlN or InN, oxides, or other crystalline compositions, the chosen temperature setpoints may be different. The heating, or ramp-up time tᵣₐₘₚ₋ᵤₚ may be between about 0.1 hour and about 200 hours, or between about 5 hours and about 96 hours. The soak time tₛₒₐₖ, during which time most or all of the crystal growth occurs, may be between about 1 hour and about 10,000 hours, between about 12 hours and about 7500 hours, or between about 100 hours and about 5000 hours. At the conclusion of the growth cycle the upper chamber 105 and the lower chamber 107 may be cooled, for example, back to room temperature, during a period of time t_{ramp-down}. The cooldown, or ramp-down time t_{ramp-down} may be between about 0.1 hour and about 200 hours, or between about 5 hours and about 96 hours.

More complicated versions of this simple profile are possible. For example, rather than heating at a constant rate, the upper and/or lower chambers may heated faster initially, and then more slowly, for example, to decrease the load on heaters 205 and 207 or on heaters 305a and 305b, depending on the type of crystal growth furnace being used. In certain embodiments, the upper zone 105 is heated sooner than lower zone 107, for example, to accelerate partial dissolution of nutrient 113. The magnitude of ΔT during the ramp-up, and its spatial distribution, may be adjusted so as to achieve a controlled degree of back-etching of seed crystals 111. Similarly, the magnitude of ΔT during the cool-down, and its spatial distribution, may be adjusted so as to minimize or optimize an extent of back-etching of the grown crystals. The magnitude of ΔT during the soak may be increased during the course of the run, for example, to increase the growth rate after initial nucleation, rather than being held constant. In addition, the profile will in general have some height dependence. For example, a value of T_{growth} near a lower portion of lower zone 107 may be larger, by between about 1 degree Celsius and about 20 degrees Celsius, than a value of T_{growth} near an upper portion of lower zone 107, to facilitate fluid transport and maintain approximately equal growth rates as a function of height. Similarly, a value of Tₙᵤₜᵣᵢₑₙₜ near a lower portion of upper zone 105 may be larger, by between about 1 degree Celsius and about 20 degrees Celsius, than a value of Tₙᵤₜᵣᵢₑₙₜ near an upper portion of upper zone 105, to facilitate fluid transport within upper zone 105. In certain embodiments, the values of tᵣₐₘₚ₋ᵤₚ, tₛₒₐₖ, and t_{ramp-down} may be different for the lower (growth) zone than for the upper (nutrient) zone.

However, the present inventors have found that, regardless of the details of the heat-up profile that is used, it is very difficult to avoid formation of wall nuclei 141, which then out-grow the seed crystals 111 for reasonable values of ΔT during the soak.

In certain embodiments, one or more surfaces within the growth region are cooled from a “growth” temperature, held at a reduced (“etch”) temperature, re-heated to the growth temperature, and held at the growth temperature for a predetermined period of time. In certain embodiments, this cool-etch-reheat-grow sequence is performed at least twice, at least 4 times, at least 5 times, at least 10 times, at least 20 times, at least 50 times, at least 100 times, at least 200 times, or at least 400 times during the growth process. In certain embodiments, the cooling, holding at a reduced (“etch”) temperature, re-heating, and holding at a higher (“growth”) temperature, is sequentially performed in a manner that can be periodic (e.g., differing periods of time to perform one or more of these steps within the performance of the steps multiple times) or cyclic (e.g., consistent periods of time to perform each step multiple times). In other embodiments, the sequential cooling, holding at a reduced temperature, re-heating, and holding at a higher temperature are performed non-periodically, with one or more individual profile-element durations that increase, decrease, or vary up and down over the course of the crystal growth run.

FIG. 5 is a schematic diagram showing an expanded view of an initial portion of a cool-etch-reheat-grow sequence according to certain embodiments of the current disclosure. After raising an average temperature of upper zone 105 to a desired value, T_{u,nutrient}, it may be held at this temperature during a soak portion of the profile (dot-dashed curve in FIG. 5). However, after raising an average temperature of lower zone 107 to a desired value, T_{l,growth}, and holding for a predetermined period of time, the average temperature of lower zone 107 may be cooled to a lower value, T_{l,etch}, over a time t_{l,cool}, held at this lower (“etchback”) temperature for a time t_{etchback}, and then re-heated to T_{l,growth} over a time t_{l,heat} and then held at this value for a time t_{growth}. In certain embodiments, as shown in FIG. 5, the value of T_{l,etch} is less than T_{u,nutrient}, so that the value of ΔT is negative during the etchback portion of the cycle. In other embodiments, T_{l,etch} may be less than T_{l,growth} but greater than T_{u,nutrient}, so that ΔT remains positive, as this may still be sufficient to etch away the wall nuclei 141. The cooling time t_{l,cool} may be between about 0.2 minute and about 4 hours, between about 0.5 minute and about 1 hour, or between about 1 minute and about 20 minutes. The etchback time t_{etchback} may be between about 1 minute and about 48 hours, between about 2 minutes and about 10 hours, or between about 3 minutes and about 4 hours. The heating time t_{l,heat} may be between about 0.5 minute and about 8 hours, between about 1 minute and about 4 hours, or between about 2 minutes and about 1 hour. The difference between T_{l,growth} and T_{l,etch} may be between about 2 degrees Celsius and about 100 degrees Celsius, between about 5 degrees Celsius and about 75 degrees Celsius, or between about 10 degrees Celsius and about 50 degrees Celsius. The difference between T_{u,nutrient} and T_{l,etch} may be between about −20 degrees Celsius and about 20 degrees Celsius, between about −5 degrees Celsius and about 15 degrees Celsius, or between about 0 degrees Celsius and about 10 degrees Celsius. The growth time t_{growth} may be between about 5 minutes and about 500 hours, between about 10 minutes about 100 hours, between about 15 minutes and about 50 hours, or between about 20 minutes and about 24 hours. An overall period of the cool-etch-reheat-grow sequence may be between about 6 minutes and about 536 hours, between about 15 minutes and about 200 hours, or between about 30 minutes and about 28 hours.

In certain embodiments, rather than cooling one or more surfaces within the growth region for an etchback process, one or more surfaces within the nutrient region are heated from a “nutrient” temperature to an elevated (“etch”) temperature, held at the elevated (“etch”) temperature, re-cooled to the nutrient temperature (growth condition), and held at the nutrient temperature for a predetermined period of time. In certain embodiments, this heat-etch-cool-grow sequence is performed at least twice, at least 5 times, at least 10 times, at least 20 times, at least 50 times, at least 100 times, at least 200 times, or at least 400 times during the growth process. In certain embodiments, the heating, holding at an elevated (“etch”) temperature, re-cooling, and holding at a lower (“nutrient/growth condition”) temperature, is sequentially performed in a periodic, cyclic, or non-periodic manner.

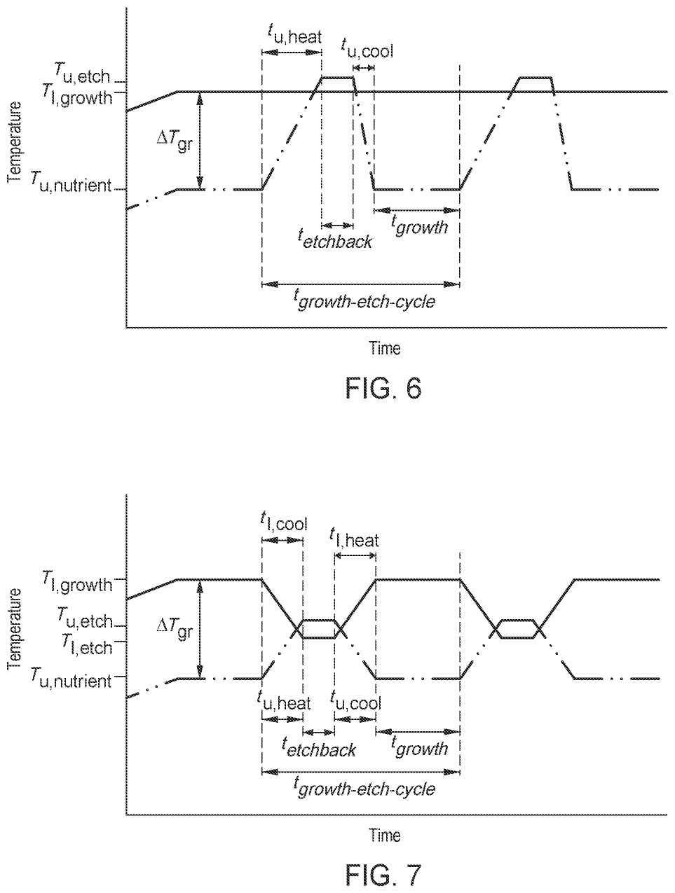

FIG. 6 is a schematic diagram showing an expanded view of an initial portion of a heat-etch-recool-grow sequence according to certain embodiments of the current disclosure. After raising an average temperature of lower zone 107 to a desired value, T_{l,growth}, it may be held at this temperature during a soak portion of the profile (solid curve in FIG. 6). However, after raising an average temperature of upper zone 105 to a desired value, T_{u,nutrient}, and holding for a predetermined period of time, the average temperature of upper zone 107 may be heated to a higher value, T_{u,etch}, over a time t_{u,heat}, held at this higher (“etchback”) temperature for a time t_{etchback}, and then re-cooled to T_{u,nutrient} over a time t_{u,cool} and then held at this value for a time t_{growth}. In certain embodiments, as shown in FIG. 5, the value of T_{l,etch} is greater than T_{l,growth}, so that the value of ΔT is negative during the etchback portion of the cycle. In other embodiments, T_{u,etch} may be greater than T_{u,nutrient} but less than T_{l,growth}, so that ΔT remains positive, as this may still be sufficient to etch away the wall nuclei 141. The heat-etch-recool-grow sequence can be repeated multiple times, and may be periodic, cyclic, or non-periodic. The heating time t_{u,heat} may be between about 0.5 minute and about 8 hours, between about 1 minute and about 4 hours, or between about 2 minutes and about 1 hour. The cooling time t_{u,cool} may be between about 0.2 minute and about 4 hours, between about 0.5 minute and about 1 hour, or between about 1 minute and about 20 minutes. The difference between T_{u,etch} and T_{u,nutrient} may be between about 2 degrees Celsius and about 100 degrees Celsius, between about 5 degrees Celsius and about 75 degrees Celsius, or between about 10 degrees Celsius and about 50 degrees Celsius. The difference between T_{u,etch} and T_{l,growth} may be between about −20 degrees Celsius and about 20 degrees Celsius, between about −5 degrees Celsius and about 15 degrees Celsius, or between about 0 degrees Celsius and about 10 degrees Celsius.

In certain embodiments, rather than holding one of a lower or upper average temperature and modulating the other, in certain embodiments both average temperatures are changed in order to effect etching of nuclei 141. For example, one or more surfaces within the growth region may be cooled, and one or more surface within the nutrient region may be heated, for an etchback process, and then restored to the growth condition and held for a predetermined period of time. In certain embodiments, this cool+heat-etch-heat+cool-grow sequence is performed at least twice, at least 5 times, at least 10 times, at least 20 times, at least 50 times, at least 100 times, at least 200 times, or at least 400 times during the growth process. In certain embodiments, the heat-etch-recool-grow sequence is sequentially performed in a periodic, cyclic, or non-periodic manner.

FIG. 7 is a schematic diagram showing an expanded view of an initial portion of a cool+heat-etch-heat+cool-grow sequence according to certain embodiments of the current disclosure. An average temperature of lower zone 107 may be raised to a desired value, T_{l,growth}, and an average temperature of upper zone 105 may be raised to a desired value, T_{u,nutrient}. After holding for a predetermined period of time, the average temperature of lower zone 107 may be heated to a higher value, T_{u,etch}, over a time t_{u,heat}, held at this higher (“etchback”) temperature for a time t_{etchback}, and then re-cooled to T_{u,nutrient} over a time t_{u,cool} and then held at this value for a time t_{growth}. In certain embodiments, as shown in FIG. 7, the value of T_{l,etch} is less than T_{u,etch}, so that the value of ΔT is negative during the etchback portion of the cycle. In other embodiments, T_{u,etch} may be greater than T_{u,nutrient} but less than T_{l,etch}, so that ΔT remains positive, as this may still be sufficient to etch away the wall nuclei 141. The heating time t_{u,heat} may be between about 0.5 minute and about 8 hours, between about 1 minute and about 4 hours, or between about 2 minutes and about 1 hour. The cooling time t_{u,cool} may be between about 0.2 minute and about 4 hours, between about 0.5 minute and about 1 hour, or between about 1 minute and about 20 minutes. The difference between T_{u,etch} and T_{u,nutrient} may be between about 2 degrees Celsius and about 100 degrees Celsius, between about 5 degrees Celsius and about 75 degrees Celsius, or between about 10 degrees Celsius and about 50 degrees Celsius. The difference between T_{u,etch} and T_{l,growth} may be between about −20 degrees Celsius and about 20 degrees Celsius, between about −5 degrees Celsius and about 15 degrees Celsius, or between about 0 degrees Celsius and about 10 degrees Celsius. In certain embodiments, the cool+heat-etch-heat+cool-grow sequence is sequentially performed in a periodic, cyclic, or non-periodic manner.

In certain embodiments, as shown in FIG. 5, the value of T_{l,etch} is less than T_{u,nutrient}, so that the value of ΔT is negative during the etchback portion of the cycle. In other embodiments, T_{l,etch} may be less than T_{l,growth} but greater than T_{u,nutrient}, so that ΔT remains positive, as this may still be sufficient to etch away the wall nuclei 141.

With each of the processes described above and illustrated schematically in FIGS. 5, 6, and 7, during the growth portion of the process the fluid flow patterns may be similar to those shown schematically in FIG. 1A. However, during the etch portion of the process the driving force for free convection flow will be reduced or even eliminated. In certain embodiments, flow may be stagnant during the etch portion of the process. In certain embodiments, a modest negative temperature gradient may be present within the growth zone during the etch portion of the process, that is, with an upper portion of growth zone 107 being cooler, by between about 1 degree Celsius and about 10 degrees Celsius, than a lower portion of growth zone 107, so that some free convection occurs within growth zone 107 even during the etch portion of the process. In other embodiments, a null or positive temperature gradient is present within the growth zone during an etch portion of the process, that is, with an upper portion of growth zone 107 being the same or warmer, by between about 0 degree Celsius and about 10 degrees Celsius, than a lower portion of growth zone 107, so that little or no free convection occurs within growth zone 107 during the etch portion of the process.

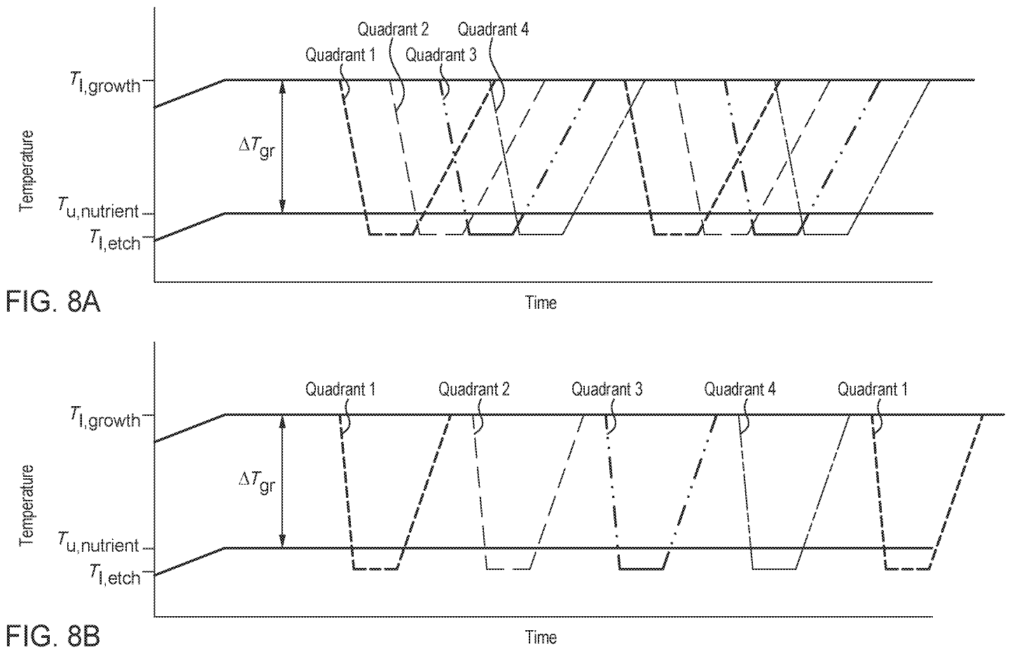

In certain embodiments, a growth-etch-growth process is carried out non-uniformly within the growth region. For example, one or more of upper-zone heaters 205a, 205b (FIG. 2), 305a (FIG. 3) and lower-zone heaters 207a, 207b (FIG. 2), 305b (FIG. 3) may be divided azimuthally, for example, into two halves, three thirds, four quadrants, eight octets, or the like. Rather than periodically cooling and heating lower-zone heaters at all azimuthal angles, as shown schematically in FIG. 5, or heating and cooling upper-zone heaters at all azimuthal angles, as shown schematically in FIG. 6, or a combination, as shown schematically in FIG. 7, different azimuthal zones may be heated and cooled at different times. For example, as shown schematically in FIGS. 8A and 8B, after raising an average temperature of upper zone 105 to a desired value, T_{u,nutrient}, it may be held at this temperature during a soak portion of the profile (solid curve in FIGS. 8A and 8B). However, after raising an average temperature of lower zone 107 to a desired value, T_{l,growth}, and holding for a first, predetermined period of time, the average temperature of a first quadrant within lower zone 107 may be cooled to a lower value, T_{l,etch}, over a time t_{l,cool}, held at this lower (“etchback”) temperature for a time t_{etchback}, and then re-heated to T_{l,growth} over a time t_{l,heat} and then held at this value for a time t_{growth}. A similar procedure may be followed with a second quadrant, a third quadrant, and a fourth quadrant within lower zone 107, with time delays, or phase lags, between the beginning of a setpoint change for one quadrant and the beginning of an analogous setpoint change for other quadrants. The temperature distribution within lower zone 107 will be non-axisymmetric, and may be complex, during such a process, generating lateral as well as vertical convective flows. In certain embodiments, the non-uniform growth-etch-regrowth process may be able to sequentially, positionally, vary or “stir” the supercritical solvent in growth zone 107 in an advantageous way. However, a non-uniform process like this may be capable of fully etching away wall nuclei 141 (cf. FIG. 1B) while producing lesser amounts of etching of seeds 111, as compared to azimuthally-uniform processes such as those shown schematically in FIGS. 5-7. Non-azimuthally-uniform analogues to the growth-etch-growth processes shown in FIGS. 6 and 7 are also possible, for example, by heating and cooling upper zone 105 quadrant by quadrant (cf. FIG. 6) or by heating and cooling both upper zone 105 and lower zone 107 quadrant by quadrant (cf. FIG. 7). While the preceding discussion focuses specifically on hot zones with four azimuthal quadrants, analogous processes with two, three, five, six, seven, eight, or more azimuthal sectors lie within the scope of the present disclosure.

In certain embodiments, such as shown schematically in FIG. 8A, one quadrant may begin to cool before a neighboring quadrant has fully-reheated back to the growth temperature T_{l,growth}. Such a process may be advantageous for ensuring that wall nuclei 141 near the boundaries of quadrants (or other azimuthal sectors) are fully etched away. However, this process may also produce more etching of seed crystals 111 than desired. In other embodiments, as shown schematically in FIG. 8B, the growth setpoints of a given quadrant or other azimuthal sector fully recover to their original value before the growth setpoints of another quadrant or other azimuthal sector are changed.

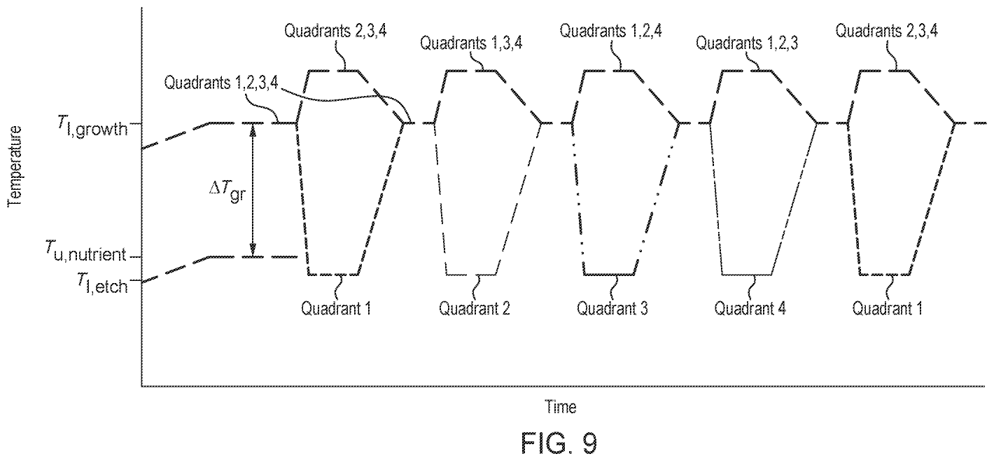

In other embodiments, as shown schematically in FIG. 9, when the setpoints of one quadrant or other azimuthal sector are changes, the setpoints of one or more other quadrants or azimuthal sectors are changed in an opposite direction, so as to partially or fully compensate for the temperature change associated with the first sector, for example, as experienced by seed crystals 111 within lower zone 107. Such a process may be able to minimize the extent of etching or reduced growth rates on seeds 111 while still enabling complete etching of wall nuclei 141.

In the embodiments described above, temperature programs for achieving growth-etch-growth cycles during a “soak” portion of the overall temperature profile. In certain embodiments, growth-etch-growth cycles, with reversals in the respective temperatures of upper zone 105 and lower zone 107, are performed during a heatup portion of the temperature profile. In certain embodiments, the magnitude of ΔT is changed, for example, increased or decreased, over the course of the soak. In certain embodiments, the period of growth-etch-growth cycles are changed during the course of the soak, for example, with the growth portion of the cycle increasing in duration while the etch portion of the cycle remains approximately the same duration. In certain embodiments, the etch cycles are discontinued after a predetermined time during the soak.

In the embodiments shown schematically in FIGS. 5-9, the temperature setpoints of only a single quadrant or azimuthal sector are changed in registry at once. However, in other embodiments, the setpoints of two or more quadrants or azimuthal sectors are changed in registry. For example, quadrants 1 and 3 may be cooled and then re-heated while quadrants 2 and 4 are held at a constant temperature and then, subsequently, quadrants 2 and 4 are cooled and then re-heated while quadrants 1 and 3 are held at constant temperature.

In the embodiments shown schematically in FIGS. 1A, 1B, and 1C, seed crystals 111 are shown as being suspended within a central portion of lower zone 107. Various means for realizing such suspension, for example, hanging from wires strung through holes in seed crystals 111 or fixing or one, two, or more edges of seed crystals 111 by means of clips, are known in the art. However, in other embodiments, seed crystals 111 are positioned close to, for example, within about 5 millimeters, within about 2 millimeters, within about 1 millimeter, within about 0.3 millimeters, or within about 0.1 millimeter, or in direct contact with a mounting surface within a growth zone. For example, one or more edges of seed crystals 111 may be pressed against the mounting surface by means of clips or the like. In such configurations, processes that are analogous to those described above and shown schematically in FIGS. 5-9 may be carried out by cycling the temperature of one or more mounting surface with respect to a region that contains nutrient 113, so as to etch away wall nuclei 141 that may form on the mounting surface. Such processes lie within the scope of the present disclosure.

The preceding discussion has focused predominantly on a solvothermal system with retrograde solubility. However, an analogous process, with growth-etch-growth cycles achieved by repetitively changing the relative temperatures in upper and lower zones within a solvothermal growth chamber, is also possible with solvothermal systems exhibiting normal solubility and lie within the scope of the present disclosure.

Group III metal nitride single crystals, for example, gallium nitride, may be grown in growth chamber 101 by the following procedure.

Seed crystals, for example, high-quality single crystal group III metal nitride, may be hung from or attached to furniture, using methods that are known in the art. The seed crystals may have a surface threading dislocation density less than about 107 cm⁻², less than about 10⁶ cm⁻², less than about 105 cm⁻², less than about 104 cm⁻², less than about 103 cm⁻², or less than about 10² cm⁻² and a stacking-fault concentration below about 104 cm⁻¹, below about 103 cm⁻¹, below about 10² cm⁻¹, below about 10 cm⁻¹ or below about 1 cm⁻¹. Polycrystalline nutrient, for example, polycrystalline group III metal nitride, may be added to a basket within the growth chamber 101.

A solid mineralizer, for example, one or more of an alkali metal such as Li, Na, K, Rb, or Cs, an alkaline earth metal, such as Be, Mg, Ca, Sr, or Ba, or an alkali or alkaline earth hydride, amide, imide, amido-imide, nitride, or azide, an ammonium halide, such as NH₄F, NH₄Cl, NH₄Br, or NH₄I, a metal halide, or a compound that may be formed by reaction of one or more of F, Cl, Br, I, HF, HCl, HBr, Hl, Ga, Al, In, GaN, AlN, InN, and NH₃ with a metal, may be added to growth chamber 101.

Growth chamber 101 may then be closed, for example, by placement of autoclave cap 217 over autoclave body 201 or by welding an end of capsule 307. Growth chamber 101 may then be evacuated, for example, through a fill tube. Residual air, moisture, and other volatile contaminants may be removed by evacuating growth chamber 101 and heating, for example, using heating elements 205/207 or 305 to a temperature between about 25 degrees Celsius and about 900 degrees Celsius, or between about 100 degrees Celsius and about 500 degrees Celsius, for a time between about 1 hour and about 1000 hours or between about 24 hours and about 250 hours. A plurality of pump/purge cycles may be employed.

In certain embodiments, a gas- or liquid-phase mineralizer may be added to growth chamber 101 according to methods that are known in the art. In one specific embodiment, the mineralizer is HF, which is added using methods taught in U.S. Patent Application 2022/0136128. In certain embodiments, a solvent is added to the internally-heated high-pressure apparatus according to methods that are known in the art. In one specific embodiment, the solvent is ammonia, which is added at an elevated pressure using methods taught in U.S. Pat. No. 8,021,481.

Growth chamber 101 is then heated to a temperature above about 400 degrees Celsius and pressurized above about 50 megapascal to perform ammonothermal crystal growth and a temperature program like one of the processes described above is applied.

In some embodiments, a crystal growth process includes providing a temperature difference between a first region of the sealable container containing the polycrystalline group III metal nitride nutrient material and a second region of the sealable container containing the at least one seed crystal, the temperature difference between the first region of the sealable container and the second region of the sealable container having a magnitude between about 1 degree Celsius and about 100 degrees Celsius and having a sign and magnitude that enables etching of the polycrystalline group III metal nitride nutrient material and single crystal growth on the at least one seed crystal; periodically reducing the magnitude and/or reversing the sign of the temperature difference between the first region of the sealable container and the second region of the sealable container so as to etch adventitious group III metal nitride nuclei that form on a surface within the second region; and depositing a single crystalline layer at least one millimeter thick on a surface of the at least one seed crystal, wherein a material layer deposition efficiency (or simply “material efficiency”), which can be defined as the weight gain of group III metal nitride material deposited on the at least one seed crystal divided by the weight gain of group III metal material deposited on all surfaces within the second region, is greater than about 60%, greater than about 75%, or greater than about 90%.

During the course of a crystal growth run, with a duration between about 24 hours and about 9000 hours, between about 48 hours and about 4000 hours, between about 96 hours and about 2000 hours, each of a plurality of seed crystals grows into a thick, free-standing ammonothermal group III metal nitride boule.

In certain embodiments, a material efficiency, which is defined as a net weight gain of seed crystals 111 divided by a quantity defined as the weight loss of polycrystalline nutrient 113 less a weight of nutrient material consumed by a chemical reaction with a mineralizer during the course of a single crystal growth run, is greater than about 50%, greater than about 60%, greater than about 70%, greater than about 80%, greater than about 90%, or greater than about 95%.

One or more free-standing ammonothermal group III metal nitride boules may reach a thickness that is greater than that of seed crystals 111 by greater than about 2 millimeters, greater than about 3 millimeters, greater than about 5 millimeters, greater than about 10 millimeters, greater than about 15 millimeters, greater than about 20 millimeters, greater than about 25 millimeters, greater than about 40 millimeters, or greater than about 100 millimeters, during the course of a single crystal growth run. In certain embodiments, the thickness direction is selected from one of [000−1], [0001], {1 0 −1 0}, or {1 0 −1 ±1}.

The distribution of various impurities within the free-standing ammonothermal group III metal nitride boule may be sampled by preparing one or more test wafers by slicing parallel to the thickness direction and performing line scans or sampling at discrete points on the test wafer by calibrated secondary ion mass spectrometry (SIMS). In certain embodiments, one or more product wafers is prepared by slicing the free-standing ammonothermal group III metal nitride boule at an angle within 32 degrees, within 24 degrees, within 16 degrees, within 11 degrees, or within 4 degrees of the thickness direction. In some embodiments, the thickness direction and the crystalline layer growth direction are essentially the same direction, for example, within 10 degrees, within 5 degrees, within 2 degrees, or within 1 degree. The product wafers may be characterized by a surface threading dislocation density less than about 107 cm⁻², less than about 10⁶ cm⁻², less than about 105 cm⁻², less than about 104 cm⁻², less than about 103 cm⁻², or less than about 10² cm⁻² and a stacking-fault concentration below about 104 cm⁻¹, below about 103 cm⁻¹, below about 10² cm⁻¹, below about 10 cm⁻¹ or below about 1 cm⁻¹. In certain embodiments, a surface of a test wafer or of a product wafer has average impurity concentrations of O, H, carbon (C), Na, and K between about 1×10¹⁶ cm⁻³ and 5×10¹⁹ cm⁻³, between about 1×10¹⁶ cm⁻³ and 8×10¹⁹ cm⁻³, below 1×10¹⁷ cm⁻³, below 1×10¹⁶ cm⁻³, and below 1×10¹⁶ cm⁻³, respectively. In certain embodiments, a surface of a test wafer or of a product wafer has impurity concentrations of O, H, C, and at least one of F and Cl between about 1×10¹⁶ cm-3 and 5×10¹⁹ cm⁻³, between about 1×10¹⁶ cm⁻³ and 8×10¹⁹ cm⁻³, below 1×10¹⁷ cm⁻³, and between about 1×10¹⁵ cm⁻³ and 1×10¹⁹ cm⁻³, respectively.

In general, the fluctuations in growth conditions represented by temperature profiles similar to those shown schematically in FIGS. 5, 6, 7, 8A-B, and 9 will give rise to fluctuations in the local impurity levels within the free-standing ammonothermal group III metal nitride boule. Typically, these fluctuations will be large enough to be measurable but will not have any significant negative impact on the properties of the crystals, for example, their crystallinity or resistance to fracture. Impurities whose concentration may vary include one or more of O, H, C, F, Cl, Na, and K, Si, Ge, and Mg. In addition, the carrier concentration, the Fermi level, and the optical absorption coefficient, for example, at one or more wavelengths between about 360 nanometers and about 750 nanometers, and/or at least one of the work function, secondary electron yield, or cathodoluminescence or photoluminescence intensity or spectrum of a surface that intersects the growth layers may vary in concert with the “growth” and “etch” cycles. In cases where the cycle times associated with varying growth conditions are fairly short, for example, between about 6 minutes and about 8 hours, it may be possible to quantify changes in the concentrations of, for example, one or more of O, H, C, F, Cl, Na, and K, by performing a SIMS sputter depth-profile through ammonothermal group III metal nitride layers in the growth direction (that is, perpendicular to a growth surface). Another option, as described above, is to prepare one or more test wafers by slicing parallel to the thickness direction. In cases where the cycle times associated with varying growth conditions are fairly long, for example, between about 12 hours and about 500 hours, it may be possible to quantify changes in impurity concentrations by performing SIMS line scans or sampling at discrete points on the test wafer along the growth-thickness direction. By preparing a second slice parallel to the first slice, that is, preparing a free-standing test wafer whose large-area surfaces are parallel to the growth direction and polishing and chemical-mechanically polishing both surfaces, the optical absorption coefficient at one or more wavelengths between about 360 nanometers and about 750 nanometers may be quantified. Another approach is to examine a test wafer in a scanning electron microscope, which can be performed with adequate spatial resolution regardless of the cycle time of the growth/etching fluctuations. The secondary electron yield and cross section for electron back-scattering are sensitive to the carrier concentration and work function, and therefore bands associated with the cyclic growth profile may be observed. Similarly, the intensity and/or wavelength of cathodoluminescence (CL) may vary along with the variations in impurity levels in the growth direction and may be observable in a scanning electron microscope equipped with a CL attachment or in a dedicated CL instrument. Similarly, the intensity and/or wavelength of photoluminescence (PL) and may be observable by scanning above-bandgap radiation (e.g., a He—Cd laser) along the growth direction of the surface of a test wafer.

The fluctuations in impurity concentrations associated with fluctuating growth conditions may have some similarities to fluctuations observed in crystals or wafers fabricated using bi-facetted growth, for example, as disclosed in U.S. Pat. No. 10,145,026. In the latter method, crystals are grown in a semipolar direction, intermediate between a <10-10> m-direction and the [000-1]-c direction in such a way that the growth front includes alternating {10-10} m-plane and {10-1-1} planes. Since the latter growth planes uptake impurities at somewhat different rates, a semipolar wafer prepared from the resulting crystal will include bands of alternating higher and lower impurity concentrations. However, an important difference between conventional methods and the processes disclosed herein is that in the conventional processes the alternating higher and lower impurity concentrations occur approximately perpendicular to the growth direction, whereas in the crystals formed by the processes disclosed herein the alternating regions of higher and lower impurity concentration will occur parallel to the growth direction. The differing distribution of the impurity concentrations between conventional processes and the process described herein is benign with respect to the grown crystal structure and the accompanying process enables higher material efficiencies and growth rates and larger crystals.

All real group III metal nitride crystals grown according to current capabilities include measurable concentrations of dislocations, for example, edge, screw, and mixed dislocations. Typically, a majority, for example, greater than 50%, greater than 65%, or greater than 80% of the dislocations present on a prepared surface of a bulk grown group III metal nitride crystal are threading dislocations, that is, extend predominantly in the direction in which the crystal was grown, locally, for example, within 30 degrees of the growth direction. The three-dimensional distribution of dislocations may be sampled and determined, for example, by comparing the location and concentration of dislocations in parallel surfaces, whose surface orientation is orthogonal to the growth direction. The parallel surfaces that are used to determine the distribution of dislocations within a formed crystal can be prepared by successive chemical mechanical polishing operations. For example, a test wafer may be prepared and its surface chemical-mechanically polished to remove subsurface damage. The location and concentration of dislocations on the surface may be determined by etch pit density measurements made by inspection, for example, in an optical or scanning electron microscope. For example, if the crystallographic orientation of the surface of the test wafer is within about 5 degrees of (0001), defect-selective etch pits may be formed by heating in molten KOH/NaOH or in a concentrated solution of H₃PO₄ or a H₃PO₄/H₂SO₄ mixture, as is well known in the art. If the crystallographic orientation of the test wafer is intermediate between m-plane and {10-1-1}, defect-selective etch pits may be formed by heating in a concentrated solution of H₃PO₄ or a H₃PO₄/H₂SO₄ mixture or in a molten flux of Na₂O₂/NaOH. After recording, for example, by digital imaging, the location of etch pits within a predetermined area of the surface of the test wafer, the surface may be chemical-mechanically polished again so that a removal thickness h of material is removed. In certain embodiments, the removal thickness h may be between about 4 microns and about 25 microns. The surface may then be defect-selective-etched again, and the location of etch pits may be determined again. If the orientation of a threading dislocation with respect to the surface normal is defined by a threading dislocation tilt angle α, then a pit on the re-chemical-mechanically-polished surface will be displaced, by comparison to a reference feature in the test wafer, by a quantity h tan(a). By comparing a digital image of the etch pit distribution on the original surface of the test wafer to the digital image obtained after removing a measured thickness h from the surface, the distribution of threading dislocation tilt angles α may be quantified. For example, consider a test wafer where an additional 10 microns was removed by chemical mechanical polishing after performing a defect-selective etch on a first surface, defining a second (parallel) surface, and a second defect-selective etch was performed on the second surface. In this case, dislocations with a threading dislocation tilt angle α, would be displaced in position by approximately 5.8 microns on the second surface, relative to their position on the first surface. In certain embodiments, therefore, at least 50%, at least 65%, or at least 80% of the etch pits on the second surface would have a position within about 5.8 microns of an etch pit on the first surface.

In certain embodiments, the three-dimensional distribution of dislocations may be determined by multi-photon photoluminescence, for example, as described by T. Tanikawa, et al., Appl. Phys. Express 11, 031004 (2018), and the orientation direction determined directly.

As disclosed in U.S. Patent Application 2023/0167586, which is hereby incorporated by reference in its entirety, there are certain advantages to growing ammonothermal group III nitride crystals with an intentional oxygen gradient in the growth direction. For example, growth rates in the <11-20> a and <10-10> m directions, relative to the [000-1] growth rate, can be increased with higher oxygen levels, enabling faster coalescence during patterned growth and flatter, more fully-planar c-plane surface morphologies. Oxygen gradients may also be beneficial in certain device applications, in order to co-optimize low ohmic losses and low contact resistance while retaining good optical transparency and thermal conductivity. Methods are taught for maintaining a maximum oxygen concentration within ammonothermal group III nitride crystals that is less than about 1×10²⁰ cm⁻³, less than about 5×10¹⁹ cm⁻³, less than about 3×10¹⁹ cm⁻³, less than about 2×10¹⁹ cm⁻³, or less than about 1×10¹⁹ cm⁻³, and a minimum oxygen concentration that is greater than about 2×10¹⁸ cm⁻³, greater than about 1×10¹⁸ cm⁻³, or greater than about 5×10¹⁷ cm⁻³. In some applications, minimum oxygen concentrations that are less than about 2×10¹⁷ cm⁻³ or less than about 1×10¹⁷ cm⁻³ may be desirable. Methods are also taught for maintaining a maximum oxygen gradient in the [0001] direction that is less than about 1×10²¹ cm⁻⁴, less than about 5×10²⁰ cm⁻⁴, or less than about 2×10²⁰ cm⁻⁴ and a minimum oxygen gradient that is greater than about 5×10¹⁶ cm⁻⁴, greater than about 2×10¹⁷ cm⁻⁴, greater than about 5×10¹⁷ cm⁻⁴, or greater than about 1×10¹⁸ cm⁻⁴. The concentration of oxygen, and the oxygen gradient during ammonothermal crystal growth, may be controlled by one or more of the following: control of the oxygen concentration and gradients thereof in polycrystalline group III nitride source material; control of the time, temperature, and atmosphere in which polycrystalline group III nitride source material is baked prior to using it for ammonothermal crystal growth; addition of a controlled quantity of Ga₂O₃ or water to the ammonothermal growth environment; control of the concentration of oxygen in silver used as a chamber liner, a capsule, or other baffle or furniture material for the ammonothermal growth process; and/or control of the time, temperature, and atmosphere in which an autoclave or capsule is baked after loading with polycrystalline nutrient and seed crystals and prior to filling with ammonia for ammonothermal crystal growth.

A method of use according to a specific embodiment is briefly outlined as follows. Provide an apparatus for high-pressure crystal growth or material processing, such as the ones described above, but there can be others, the apparatus comprising an interior region (for example, cylindrical in shape) surrounded by radial and axial restraint structures, and a closable opening region to the interior region; provide one or more raw materials to the interior region and close and seal the opening region; provide a solvent to the interior region; provide the apparatus with thermal energy to cause an increase in temperature within the interior region to greater than 200 degrees Celsius to cause the solvent to be superheated; form a crystalline material from a process of the superheated solvent; remove thermal energy from the apparatus to cause a temperature of the capsule to change from a first temperature to a second temperature, which is lower than the first temperature; release the solvent from the interior region; open an opening region to the interior region of the high-pressure apparatus; remove the crystalline material from the interior region; and perform other steps, as desired. This sequence of steps provides a method according to an embodiment of the present disclosure. In a specific embodiment, the present disclosure provides a method and resulting crystalline material provided by a high-pressure apparatus where an elevated temperature is applied directly to seed crystals. Other alternatives can also be provided where steps are added, one or more steps are removed, or one or more steps are provided in a different sequence without departing from the scope of the claims herein. Details of the present method and structure can be found throughout the present specification and more particularly below.

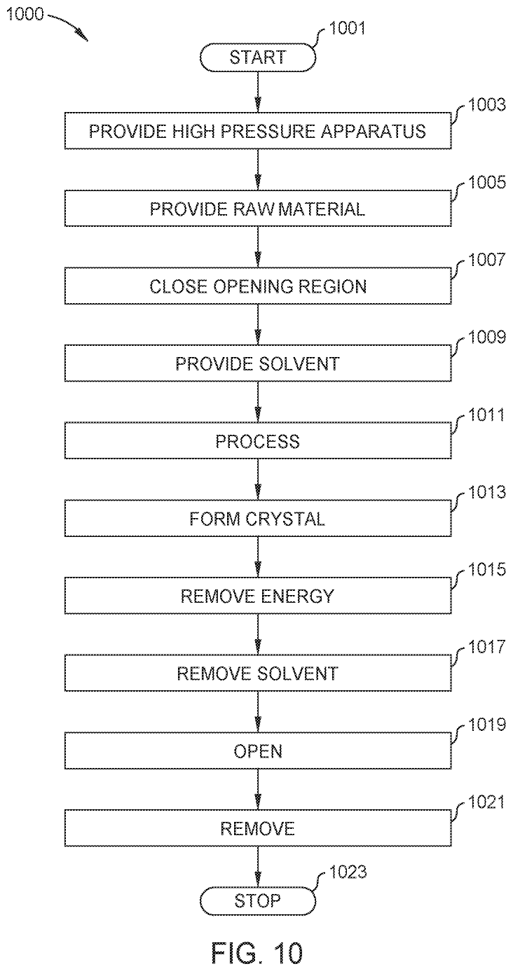

FIG. 10 is a simplified flow diagram 1000 of a method of processing a material within a supercritical fluid. This diagram is merely an example, which should not unduly limit the scope of the claims herein.

In a specific embodiment, the method begins with start, step 1001. The method begins by providing an apparatus for high-pressure crystal or material processing (see step 1003), such as the one described above, but there can be others. In certain embodiments, the apparatus has an interior region (for example, cylindrical in shape) surrounded by radial and axial restraint structures. In certain embodiments, the opening region to the interior region are closable by lid closure or welded structures.

In a specific embodiment, the method provides at least one raw material to the interior region (see step 1005), followed by closing an opening region (see step 1007) and providing a solvent, such as ammonia into the interior region (see step 1009), for example. In a specific embodiment, the raw materials include seed crystals and polycrystalline nutrient material. The method heats the interior region (see step 1011) with thermal energy to cause an increase in temperature within the interior region to greater than 200 degrees Celsius to cause the solvent to be superheated and process the at least one raw material in the interior region.

Referring again to FIG. 10, the method forms a crystalline material (see step 1013) from a process of the superheated solvent. In certain embodiments, the crystalline material comprises a gallium-containing nitride crystal such as GaN, AlGaN, InGaN, and others. In a specific embodiment, the method removes thermal energy from the capsule (see step 1015) to cause a temperature within the interior region to change from a first temperature to a second temperature, which is lower than the first temperature. Once the energy has been removed and temperature reduced to a suitable level, the method removes a solvent from the interior region (step 1017).

In a specific embodiment, the interior region is opened, step 1019. In a specific embodiment, the crystalline material is removed from the interior region, step 1021. Depending upon the embodiment, there can also be other steps, which can be inserted or added, or certain steps can also be removed. In a specific embodiment, the method ends at stop, step 1023.

The above sequence of steps provides a method according to an embodiment of the present disclosure. In a specific embodiment, the present disclosure provides a method and resulting crystalline material provided by a high-pressure apparatus where an elevated temperature is applied directly to seed crystals. Other alternatives can also be provided where steps are added, one or more steps are removed, or one or more steps are provided in a different sequence without departing from the scope of the claims herein.

In certain embodiments, a gallium-containing nitride crystal or boule grown by methods such as those described above is sliced or sectioned to form wafers. The slicing, sectioning, or sawing may be performed by methods that are known in the art, such as internal diameter sawing, outer diameter sawing, fixed abrasive multiwire sawing, fixed abrasive multiblade sawing, multiblade slurry sawing, multiwire slurry sawing, ion implantation and layer separation, or the like. The wafers may be lapped, polished, and chemical-mechanically polished according to methods that are known in the art.

One or more active layers may be deposited on the well-crystallized gallium-containing nitride wafer. The active layer may be incorporated into an optoelectronic or electronic devices such as at least one of a light emitting diode, a laser diode, a photodetector, a photodiode, an avalanche photodiode, a transistor, a rectifier, and a thyristor; one of a transistor, a rectifier, a Schottky rectifier, a thyristor, a p-i-n diode, a metal-semiconductor-metal diode, high-electron mobility transistor, a metal semiconductor field effect transistor, a metal oxide field effect transistor, a power metal oxide semiconductor field effect transistor, a power metal insulator semiconductor field effect transistor, a bipolar junction transistor, a metal insulator field effect transistor, a heterojunction bipolar transistor, a power insulated gate bipolar transistor, a power vertical junction field effect transistor, a cascode switch, an inner sub-band emitter, a quantum well infrared photodetector, a quantum dot infrared photodetector, a solar cell, and a diode for photoelectrochemical water splitting and hydrogen generation.

### EXAMPLES

Embodiments provided by the present disclosure are further illustrated by reference to the following examples. It will be apparent to those skilled in the art that many modifications, both to materials and methods, may be practiced without departing from the scope of the disclosure.

### Example 1

In this example, 28 c-plane GaN seed crystals were hung from silver wires and placed in a silver capsule having an inner diameter of 5.6 inches, along with 3.1 kg of polycrystalline GaN nutrient material that had been baked at 210 degrees Celsius for approximately 16 hours. The capsule was baked out, under vacuum, at a temperature of approximately 200 degrees Celsius for approximately 6 hours. The capsule was filled with 97.2 g of HF mineralizer and 2.36 kg of ammonia and sealed. The lower end of the capsule was heated to a temperature of approximately 684 degrees Celsius and the upper end to a temperature of approximately 669 degrees Celsius. The upper end temperature was held at this value for approximately 200 hours. The bottom end temperature was held at 684 degrees Celsius for 1.5 hour, cooled to 664 degrees Celsius over approximately 4 minutes, held at this lower “etch” temperature for approximately 10 minutes, then heated back to the upper “growth” temperature of 684 degrees Celsius over approximately 5 minutes and held for another 1.5 hour. This cyclic process was repeated another 111 times. The capsule was then cooled, opened, and the grown crystals were removed. The average growth rate on the seed crystals was approximate 4.5 micrometers per hour. The material efficiency, that is, the fraction of GaN that was transported from the nutrient region to the growth region that ended up on the seed crystals, was 100%. No nucleated GaN crystals were observed on the inner diameter of the capsule.

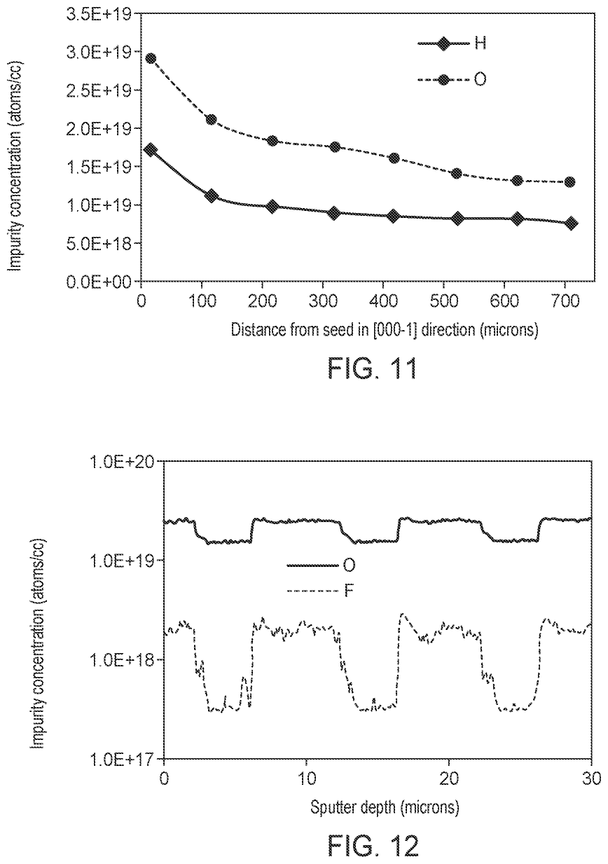

One of the grown crystals was sliced at an angle of approximately 3 degrees from c-plane, exposing the grown thickness over a wide wedge surface. Approximately 109 lighter-color fringes, believed to represent the start of each growth cycle, were visible on the wedge surface. The average spacing between the growth cycle fringes was approximately 4.9 micrometers on this particular crystal, calculated normal to the as-grown c-plane surface. SIMS was performed at several positions along the wedge surface and the concentrations of O and H as a function of distance in the [000-1] direction from the seed surface were determined. The results of the process performed in Example 1 are shown in FIGS. 11 and 12. As shown in FIG. 12, bands in the grown crystalline layer, which are described further below, are formed due to the cyclic process performed in Example 1.

The N-face surface of another one of the grown crystals was polished approximately parallel to the (000-1) orientation, and the outermost 30 microns of the sample was analyzed by depth-profile SIMS. The concentrations of oxygen and fluorine, as a function of depth, is shown in FIG. 12. During the growth/etch cycles, the oxygen concentration varied approximately periodically between about 1.5×10¹⁹ cm⁻³ and about 2.5×10¹⁹ cm⁻³ and the fluorine concentration varied periodically, in phase, between about 3.6×10¹⁷ cm⁻³ and about 2.1×10¹⁸ cm⁻³. In this region of the crystal, the period of the impurity concentration variations was approximately 10 microns. As shown in FIG. 11, the O and H concentration in the grown crystalline layer desirably decreased as the thickness of the grown layer increased over a length scale of hundreds of microns. As shown in FIG. 12, the grown crystalline layer included a plurality of formed bands that included a bimodal distribution of O and F concentration levels as the thickness of the grown crystalline layer increased. The slow decrease in the average oxygen concentration, readily apparent in FIG. 11, is not visible in FIG. 12, which has a range of only 30 microns and the sampling was performed at a location that was nearly 700 microns from the seed.

### Example 2

In this example, 34 c-plane GaN seed crystals were hung from silver wires and placed in a silver capsule having an inner diameter of 5.6 inches, along with 3.8 kg of polycrystalline GaN nutrient material that had been fired in ammonia at a temperature of approximately 835 degrees Celsius for approximately 4 hours. The capsule was baked out, under vacuum, at a temperature of approximately 250 degrees Celsius for approximately 40 hours. The capsule was filled with 94.0 g of HF mineralizer and 2.43 kg of ammonia and sealed. The lower end of the capsule was heated to a temperature of approximately 685 degrees Celsius and the upper end to a temperature of approximately 669 degrees Celsius. The upper end temperature was held at this value for approximately 620 hours. The bottom end temperature was held at 684 degrees Celsius for 1.5 hour, cooled to 664.5 degrees Celsius over approximately 4.2 minutes, held at this lower “etch” temperature for approximately 12 minutes, then heated back to the upper “growth” temperature of 684 degrees Celsius over approximately 4.8 minutes and held for another 1.5 hour. This cyclic process was repeated another 310 times. The capsule was then cooled, opened, and the grown crystals were removed. The average growth rate on the seed crystals was approximate 2.5 micrometers per hour. The material efficiency, that is, the fraction of GaN that was transported from the nutrient region to the growth region that ended up on the seed crystals, was 100%. No nucleated GaN crystals were observed on the inner diameter of the capsule at the end of the process run.

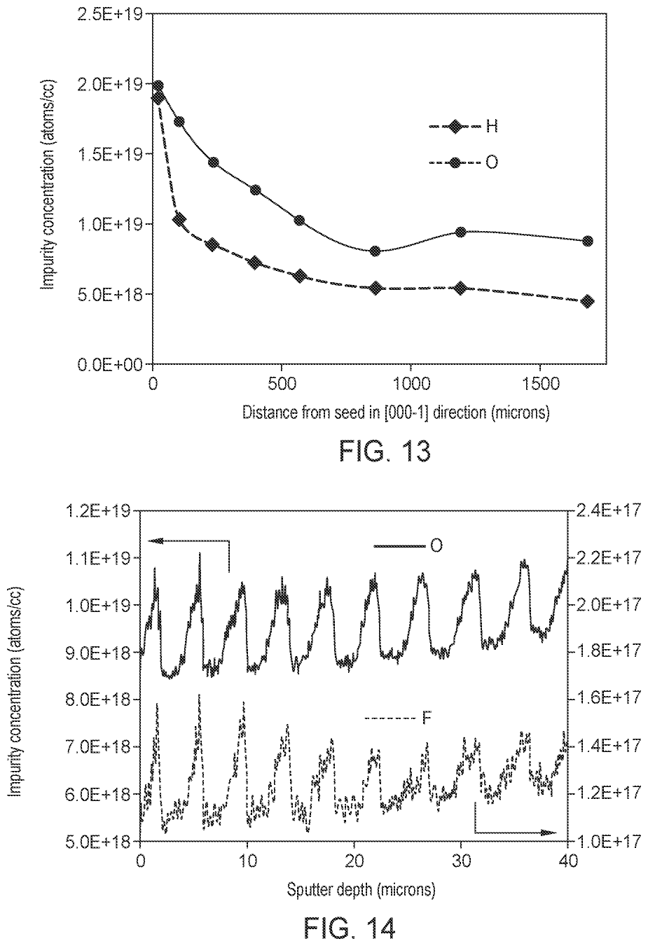

One of the grown crystals was sliced at an angle of approximately 6 degrees from c-plane, exposing the grown thickness over a wide wedge surface. SIMS was performed at several positions along the wedge surface and the concentrations of O and H as a function of distance from the growth surface were determined. The results of the process performed in Example 2 are shown in FIGS. 13 and 14. As similarly shown in FIG. 11, FIG. 13 shows the O and H concentration in the grown crystalline layer desirably decreasing as the thickness of the grown layer increased.

The N-face surface of another one of the grown crystals was polished approximately parallel to the (000-1) orientation, and the outermost 40 microns of the sample was analyzed by depth-profile SIMS. The concentrations of oxygen and fluorine, as a function of depth, is shown in FIG. 14. During the growth/etch cycles, the oxygen concentration varied periodically between about 9×10¹⁸ cm³ and about 1.1×10¹⁹ cm⁻³ and the fluorine concentration varies periodically, in phase, between about 1.1×10¹⁷ cm⁻³ and about 1.5×10¹⁷ cm⁻³. As shown in FIG. 14, the grown crystalline layer included a plurality of formed bands that included a bimodal distribution of O and F concentration levels as the thickness of the grown crystalline layer increased. In the case of FIG. 14, unlike FIG. 12, a slight increase in the average oxygen concentration with depth (i.e., decreasing distance to the seed) is visible.

### Example 3

In this example, 27 c-plane GaN seed crystals were hung from silver wires and placed in a silver capsule having an inner diameter of 5.6 inches, along with 2.2 kg of polycrystalline GaN nutrient material that had been fired in ammonia at a temperature of approximately 835 degrees Celsius for approximately 4 hours. The capsule was baked out, under vacuum, at a temperature of approximately 250 degrees Celsius for approximately 40 hours. The capsule was filled with 97.5 g of HF mineralizer and 2.36 kg of ammonia and sealed. The lower end of the capsule was heated to a temperature of approximately 680 degrees Celsius and the upper end to a temperature of approximately 669 degrees Celsius. The upper end temperature was held at this value for approximately 357 hours. The bottom end temperature was held at 680 degrees Celsius for 12 hours, cooled to 664.5 degrees Celsius over approximately 2 minutes, held at this lower “etch” temperature for approximately 12 minutes, then heated back to the upper “growth” temperature of 680 degrees Celsius over approximately 5 minutes and held for another 12 hours. This cyclic process was repeated another 27 times. The capsule was then cooled, opened, and the grown crystals were removed. The average growth rate on the seed crystals was approximate 3.9 micrometers per hour. The material efficiency, that is, the fraction of GaN that was transported from the nutrient region to the growth region that ended up on the seed crystals, was approximately 87%. Some isolated GaN crystals had nucleated on the inner diameter of the capsule, qualitatively similar to the schematic illustration of FIG. 1B, but their concentration was modest in distribution across the exposed surface area of the capsule wall.

One of the grown crystals was sliced at an angle of approximately 3 degrees from c-plane, exposing the grown thickness over a wide wedge surface. SIMS was performed at several positions along the wedge surface and the concentrations of O and H as a function of distance from the growth surface were determined. The results of the process performed in Example 3 are shown in FIG. 15. As similarly shown in FIGS. 11 and 13, FIG. 15 shows the O and H concentration in the grown crystalline layer desirably decreasing as the thickness of the grown layer increased.

In this case, due to the higher thickness deposited during the growth portion of the cycle, compared to Examples 1 and 2 (growth time in each cycle of of 12 hours, rather than 1.5 hr), it was not practical to observe the formed bands by sputter-depth-profiling. However, a cross section was prepared from another grown crystal, by cleaving, and examined in a scanning electron microscope. Using back-scattered electrons, under a channeling contrast imaging condition, it was possible to observe narrow bright bands associated with the growth/etch cycles, with a locally-averaged spacing of approximately 38 microns.

Without wishing to be bound by theory, several mechanisms for the behavior shown in FIGS. 12 and 14 seem possible. First, the etch process may cause local roughening of the surface of the growing crystals. Re-growth on the roughened crystals may incorporate a higher level of impurities. Then, after the surface morphology has re-established a smoother steady state, the level of impurities in the grown crystals may decrease. Second, it is possible that the growth rate on the seeds is reduced during the etch portion of the cycle, relative to the growth portion of the cycle, but that actual etching of the seeds does not occur (unlike the case with wall nuclei). A reduced growth rate during the etch portion of the cycle may be accompanied by a reduced impurity uptake. However, a lower growth temperature during the etch portion of the cycle could, conversely, be accompanied by a higher impurity update. Third, it is also possible that the reversal of the flow (circulating during the growth cycle, as shown schematically in FIG. 1A, to stagnant during the etch cycle) during the etch cycle may re-introduce impurities into the growth environment, causing an increase in the impurity levels as crystal growth re-initiates. After a period, the elevated impurity levels in the growth environment may be depleted and the impurity levels in the grown crystals may return to a local baseline level.

We note that the detailed concentration profiles in FIGS. 14 and 12 are different. In FIG. 14, the impurity concentrations rise rapidly and then decay more slowly (recall that the growth direction is from greater sputter depths to shallower sputter depths), whereas in FIG. 12 the impurity concentrations are more bi-modal (high and low). The detailed explanation is not yet understood, but may be impacted by the details of the cooldown times, etch times, heatup times, and the precise values of the temperatures during each cycle. For example, it is possible that a longer etch cycle (such as in Example 2) will liberate more impurities from the already-grown but now dissolving crystal and add to the solution surrounding the crystal. This might increase the overall concentration of impurities in the solution and therefore forming a longer-lasting reservoir so that the rectangle-shape profile in FIG. 12 can be changed to a more sawtooth like profile as shown in FIG. 14.

For a three-dimensional seed crystal, bands containing alternating impurity levels associated with the growth-etch-regrowth process may form on all seed surfaces that are exposed to the crystal growth environment. Typically, the seed crystals 111 will have one or two surfaces that are larger in surface area than that of edges of the seed crystals and, in the sectors that form above these surfaces, the bands should be substantially parallel, at least insofar as the growing surfaces remain smooth and planar. In certain embodiments, a large area seed surface with have a crystallographic orientation within about 5 degrees, within about 2 degrees, or within about 1 degree of (000±1), of (10-10) and the bands will be substantially parallel to this orientation. Depending on the lengths of the growth and etch cycles, the period associated with elevated versus reduced impurity levels in sub-bands may vary between about 0.1 micrometer and about 500 micrometers, between about 0.5 micrometers and about 250 micrometers, between about 1 micrometer and about 100 micrometers, or between about 3 micrometers and about 50 micrometers.

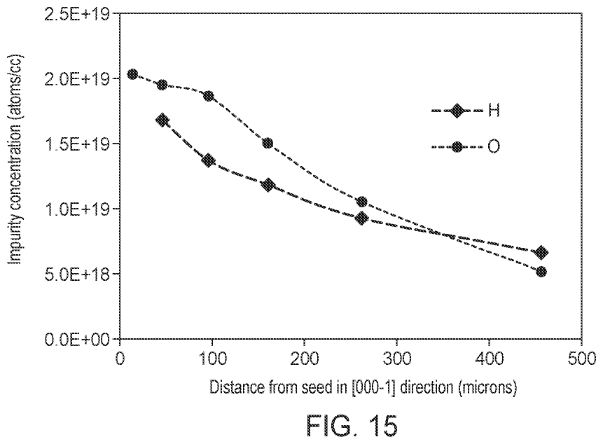

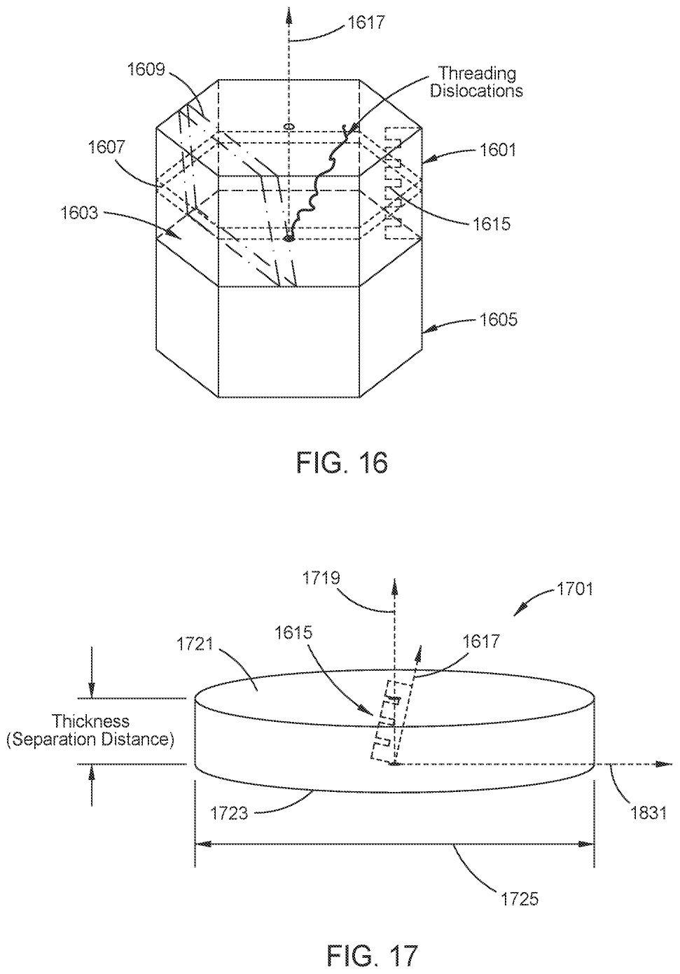

FIG. 16 is a schematic diagram showing a grown crystal 1601 formed on a large-area surface 1603 of a seed crystal 1605. For simplicity, growth on other surfaces of seed crystal 1605, and possible formation of other facets, such as semipolar facets, is not shown. In this particular example, seed crystal 1605 has a hexagonal shape and large-area surface 1603 has a crystallographic orientation within 5 degrees of (0 0 0 −1). However, other seed shapes are possible. In addition, large-area surface 1603 can have another orientation, for example, within 5 degrees of (0 0 0 1), {1 0 −1 0}, {1 0 −1 ±1}, or {1 0 −1 ±2}.

In certain embodiments, a crystal or wafer containing bands with alternating impurity concentrations 1615 may be prepared by slicing grown crystal 1601 along a first slice orientation 1607 to form one or more wafers having a surface normal 1719 within about 10 degrees, within about 5 degrees, within about 2 degrees, or within about 1 degree of the growth direction 1617, for example, one of [000±1], <10-10>, <10-1±1>, and <10-1±2>. The edges of the sliced crystal may be ground, forming a wafer 1701, as shown schematically in FIG. 17. One or more orientation flats, chamfers, or the like, may be added, as is well known in the art. The number of parallel bands within the wafer may be substantially reduced, relative to the number of bands in the as-grown crystal, for example, to at least four, at least eight, or at least 10 bands. In certain embodiments, each band includes a first sub-band having a concentration of at least one impurity selected from H, O, Li, Na, K, F, Cl, Br, and I that is higher, by a factor of at least about 1.05, about 1.1, about 1.2, or about 1.5, and less than about 5, about 10, or about 100, than a concentration of the same impurity within a second sub-band.

In certain embodiments, wafer 1701 has a first surface 1721 having a normal 1719 that is within about 10 degrees, within about 5 degrees, within about 2 degrees, or within about 1 degree of a growth direction 1617 of the ammonothermal group III nitride crystal, for example, one of [000-1], [0001], {1 0 −1 0}, {1 0 −1 ±1}, or {1 0 −1 ±2}, and may have a diameter 1725 (also referred to herein as the maximum edge-to-edge dimension) of at least 40 millimeters, at least 70 millimeters, at least 90 millimeters, at least 140 millimeters, or at least 190 millimeters, and a thickness between about 200 micrometers and about 2000 micrometers, between about 225 micrometers and about 1000 micrometers, or between about 250 micrometers and about 600 micrometers. In certain embodiments, at least 50%, at least 65%, or at least 80% of the dislocations present on the first surface are characterized by a threading dislocation tilt orientation that is within 30 degrees of the growth direction 1617 or to a normal 1719 to the first surface (that is, are threading dislocations).

As noted above, the yield and quality of the crystal containing bands with alternating impurity concentrations 1615, and a near-c-plane wafer (for example) prepared therefrom, may be improved by the presence of a gradient in the concentration of oxygen through its thickness, which may be accompanied by a gradient in hydrogen and/or fluorine. The average oxygen concentration within a depth of 2 to 10 micrometers on the first surface 1721 may be greater, by a factor between about 1.1 and about 10, or by a factor between about 1.1 and about 3, than the average oxygen concentration within a depth of 2 to 10 micrometers on the opposing surface 1723, as quantified by calibrated secondary ion mass spectrometry. The first surface 1721 may be characterized by a stacking fault concentration below about 103 cm⁻¹, below about 10² cm⁻¹, below about 10 cm⁻¹, or below about 1 cm⁻¹. The wafer may be characterized by a total thickness variation (TTV) below about 30 micrometers, below about 20 micrometers, below about 10 micrometers, or below about 5 micrometers.

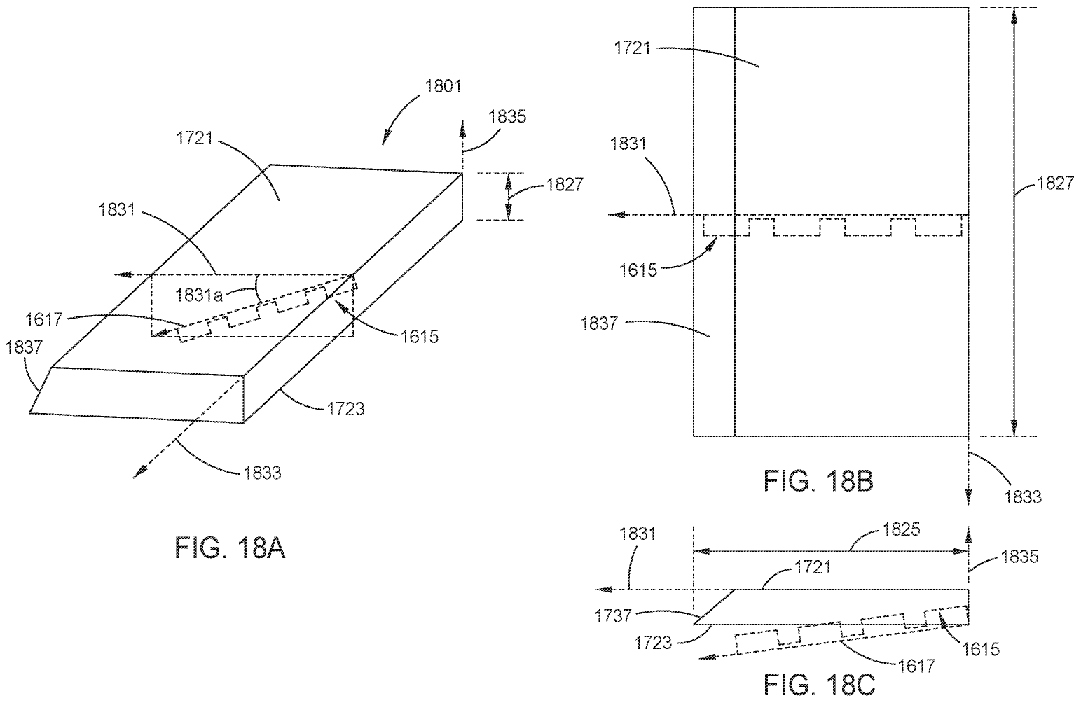

Referring again to FIG. 16 and also to FIGS. 18A-18C, in certain embodiments, grown crystal 1601 containing bands with alternating impurity concentrations 1615 may be sliced instead along a second slice orientation 1609 to form one or more wafers 1801 having a first surface 1721 with a crystallographic orientation within 30 degrees of being orthogonal to the growth direction 1617, for example, a nonpolar or semipolar orientation, a maximum edge-to-edge dimension 1825 greater than 5 millimeters in a first direction 1831, the first direction 1831 being within 30 degrees (e.g., angle 1831a in FIG. 18A) of the growth direction 1617, and a maximum edge-to-edge dimension 1827 greater than 15 millimeters in a second direction 1833 orthogonal to the first direction 1831 may be prepared using the methods described above. A schematic illustration of a wafer formed in this way is shown schematically in FIGS. 18A-18C. FIG. 18A illustrates an isometric view of a first surface 1721 of a wafer 1801 formed by slicing the grown crystal 1601 along the second slice orientation 1609. FIG. 18B is a plan view of the first surface 1721 of a wafer 1801 illustrated in FIG. 18A. FIG. 18C is a side edge view of the grown crystal 1601 as viewed in the negative second direction 1833. In this particular example the wafer has a substantially rectangular shape, but other shapes are possible. The wafer 1701 may have a thickness, in a third direction 1835 that is orthogonal to the first direction 1831 and the second direction 1833, between the first surface and a second surface 1723 opposite the first surface that is between about 100 micrometers and about 1000 micrometers, or between about 200 micrometers and about 600 micrometers. In certain embodiments, at least 50%, at least 65%, or at least 80% of the dislocations present on the first surface are characterized by a threading dislocation tilt orientation that is within 30 degrees of a growth direction 1617 (that is, are threading dislocations). The presence and orientation of the threading dislocations may be observed and quantified by performing defect-selective etching of a third surface, where the third surface has an orientation that is within 60 degrees, such as within 45 degrees, or 30 degrees, or even 20 degrees of being perpendicular to the first direction 1831. The wafer may be characterized by a number of parallel bands having varying impurity concentrations along the first surface in the first direction 1831, for example, between about four and about 10,000, between about 10 and about 5000, or between about 25 and about 1000. In certain embodiments, each band includes a first sub-band having a concentration of at least one impurity selected from H, O, Li, Na, K, F, Cl, Br, and I that is higher, by a factor of at least about 1.05, about 1.1, about 1.2, or about 1.5, and less than about 5, about 10, or about 100, than a concentration of the same impurity within a second sub-band. In addition, by virtue of the presence of an oxygen gradient in the [0 0 0 1] direction, the wafer may be characterized by an oxygen concentration having a minimum value, as measured by scanning in the first direction, between about 2×10¹⁷ cm⁻³ and about 1×10¹⁹ cm⁻³, or between about 5×10¹⁷ cm⁻³ and about 6×10¹⁸ cm⁻³, at a first position along the first surface, and increasing to a maximum value between about 1×1 0¹⁸ cm⁻³ and about 5×10¹⁹ cm⁻³, between about 1.5×10¹⁸ cm⁻³ and about 2×10¹⁹ cm⁻³, or between about 2×10¹⁸ cm⁻³ and about 1.2×10¹⁹ cm⁻³, at a second position along the first direction 1831, the second position being separated from the first position in the first direction 1831 by a distance between 1 millimeter and 25 millimeters, or between about 2 millimeters and about 10 millimeters. In addition, based on a correlation between the concentration of oxygen in ammonothermal group III nitride with the optical absorption coefficient, the wafer may be characterized by an optical absorption coefficient at a wavelength of 450 nanometers having a minimum value, as measured by scanning in the first direction 1831, between about 0.1 cm⁻¹ and about 5 cm⁻¹, or between about 0.25 cm⁻¹ and about 3 cm⁻¹, at a first position along the first surface, and increasing to a maximum value between about 0.5 cm⁻¹ and about 25 cm⁻¹, between about 0.75 cm⁻¹ and about 10 cm⁻¹, or between about 1 cm⁻¹ and about 6 cm⁻¹, at a second position along the first direction 1831, the second position being separated from the first position in the first direction 1831 by a distance between 1 millimeter and 25 millimeters, or between about 2 millimeters and about 10 millimeters.

In some embodiments, one or more of the processing systems described herein, such as the autoclave 200 or the internally-heated high-pressure apparatus 300, includes a system controller that is configured to enable the performance of one or more of the processing methods described herein. The system controller will include a central processing unit (CPU), a memory, and support circuits. The system controller is used to control the process sequence used to form a free-standing crystal, comprising a group III metal and nitrogen. The CPU is a general-purpose computer processor configured for use in an industrial setting for controlling the processing chamber and sub-processors related thereto. The memory described herein, which is generally non-volatile memory, may include random access memory, read-only memory, floppy or hard disk drive, or other suitable forms of digital storage, local or remote. The support circuits are conventionally coupled to the CPU and comprise cache, clock circuits, input/output subsystems, power supplies, and the like, and combinations thereof. Software instructions (program) and data can be coded and stored within the memory for instructing a processor within the CPU. A software program (or computer instructions) readable by CPU in the system controller determines which tasks are performable by the components in the processing system.

Typically, the program, which is readable by CPU in the system controller, includes code, which, when executed by the processor (CPU), performs tasks relating to the methods described herein. The program may include instructions that are used to control the various hardware and electrical components within the processing system to perform the various process tasks and various process sequences used to implement the methods described herein. In one embodiment, the program includes instructions that are used to perform one or more of the operations described above in relation to FIGS. 4-10.

Embodiments of the disclosure can include an apparatus for solvothermal crystal growth. The apparatus comprising: a pressure vessel having a cylindrical shaped portion extending between a top end and a bottom end of the pressure vessel; a cylindrical heater having an upper zone and a lower zone that are each disposed around the cylindrical shaped portion; a sealable container positioned within the cylindrical shaped portion of the pressure vessel, and a computer readable medium containing program instructions, wherein execution of the program instructions by one or more processors of a system controller causes the one or more processors to carry out a method of forming a group III metal nitride boule or wafer. The method includes: forming a single crystalline layer at least one millimeter thick on a surface of at least one seed crystal, wherein forming the single crystalline layer comprises: heating the sealable container to a temperature above about 200 degrees Celsius by use of the cylindrical heater, wherein an interior region of the sealable container comprises the at least one seed crystal, a polycrystalline group III metal nitride nutrient material, a mineralizer material, and ammonia, a first region of the interior region comprises the polycrystalline group III metal nitride nutrient, a second region of the interior region comprises the at least one seed crystal, and the heating of the sealable container causes a pressure within interior region of the sealable container to be above about 50 megapascals. The method also includes sequentially adjusting a temperature difference between the first region and the second region, wherein the temperature difference has a magnitude between about 1 degree Celsius and about 100 degrees Celsius and a positive or a negative sign, and the magnitude and/or sign of the sequentially adjusted temperature difference is performed at least once during the formation of the single crystalline layer. The thickness of the formed single crystal layer can be measured in a first growth direction, and at least 50% of dislocations formed in the formed single crystal layer have an orientation within 60 degrees, such as 45 degrees, 30 degrees, or even 20 degrees of the first growth direction. The thickness of the formed single crystal layer can be measured in a first growth direction and the formed single crystal layer comprises an oxygen gradient that decreases in the first growth direction extending from the surface of the at least one seed crystal. In some embodiments the process of forming the single crystalline layer further comprises: sequentially depositing a plurality of sub-bands at a material efficiency greater than 60%, wherein material efficiency is defined as a weight gain of group III metal nitride material deposited on the at least one seed crystal divided by a weight gain of group III metal material deposited on all surfaces within the second region.

While the foregoing is directed to embodiments of the present disclosure, other and further embodiments of the disclosure may be devised without departing from the basic scope thereof, and the scope thereof is determined by the claims that follow.

What is claimed is:

1. A free-standing crystal, comprising a group III metal and nitrogen, wherein the free-standing crystal comprises:
a wurtzite crystal structure;
a growth direction, the growth direction being selected from one of [0 0 0 ±1], {1 0 −1 0}, {1 0 −1±1}, or {1 0 −1 ±2};
a first surface having a maximum edge-to-edge dimension in a first direction; and
a second surface on the opposite side of the crystal from the first surface, and is separated from the first surface in a second direction that is orthogonal to the first direction and to the first surface, the second direction being within 10 degrees of the growth direction,
wherein:
the first surface is characterized by a dislocation density between 1 cm⁻² and 107 cm⁻², at least 50% of the dislocations having an orientation within 30 degrees of the growth direction, an average impurity concentration of H greater than 10¹⁷ cm⁻³, and an average impurity concentration of at least one of Li, Na, K, F, Cl, Br, and I greater than 10¹⁵ cm⁻³, as quantified by calibrated secondary ion mass spectrometry, and
the free-standing crystal is characterized by at least four sets of bands, wherein
each set of bands includes a first sub-band and a second sub-band, the first sub-band having a concentration of at least one impurity selected from H, O, Li, Na, K, F, Cl, Br, and I that is higher, by a factor between about 1.05 and about 100, than a concentration of the same impurity within the second sub-band; and
each of the at least four sets of bands have at least portions that are substantially parallel, a thickness of each of the at least four sets of bands in the growth direction being between about 0.1 micrometer and about 500 micrometers.

2. The free-standing crystal of claim 1, wherein
the maximum edge-to-edge dimension of the first surface is greater than 40 millimeters in the first direction, and
a separation between the first surface and the second surface is between about 200 micrometers and about 2000 micrometers in the second direction.

3. The free-standing crystal of claim 1, wherein an average oxygen concentration within a depth of 2 to 10 micrometers from the first surface, measured at at least four regions, is between 1×10¹⁶ cm⁻³ and 5×10¹⁹ cm⁻³ and is greater, by a factor between about 1.1 and about 10, than the average oxygen concentration within a depth of 2 to 10 micrometers from the second surface, measured at at least four regions, as quantified by calibrated secondary ion mass spectrometry.

4. A free-standing crystal, comprising a group III metal and nitrogen, wherein the free-standing crystal comprises:
a wurtzite crystal structure;
a growth direction, the growth direction being selected from one of [0 0 0 ±1], {1 0 −1 0}, {1 0 −1±1}, or {1 0 −1±2};
a first surface having a maximum edge-to-edge dimension greater than 5 millimeters in a first direction, the first direction being within 30 degrees of the growth direction;
a second surface on the opposite side of the crystal from the first surface, and is separated from the first surface in a second direction that is orthogonal to the first direction and to the first surface; and
a third surface having an orientation that is within 60 degrees of being perpendicular to the first direction,
wherein:
the third surface is characterized by a dislocation density between 1 cm⁻² and 107 cm⁻², at least 50% of the dislocations having an orientation within 30 degrees of the growth direction,
the first surface is characterized by an average impurity concentration of H greater than 10¹⁷ cm⁻³, and an average impurity concentration of at least one of Li, Na, K, F, Cl, Br, and I greater than 10¹⁵ cm⁻³, as quantified by calibrated secondary ion mass spectrometry;
the free-standing crystal is characterized by at least four sets of bands, wherein
each set of bands includes a first sub-band and a second sub-band, the first sub-band having a concentration of at least one impurity selected from H, O, Li, Na, K, F, Cl, Br, and I that is higher, by a factor between about 1.05 and about 100, than a concentration of the same impurity within the second sub-band; and
each of the at least four sets of bands have at least portions that are substantially parallel, a thickness of each of the at least four sets of bands in the growth direction being between about 0.1 micrometer and about 500 micrometers.

5. The free-standing crystal of claim 4, wherein a separation between the first surface and the second surface is between about 200 micrometers and about 2000 micrometers in the second direction.

6. The free-standing crystal of claim 4, wherein an average concentration of stacking faults on the first surface is below 103 cm⁻¹, wherein the crystal is characterized by an oxygen concentration having a minimum value between 2×10¹⁷ cm⁻³ and 1×10¹⁹ cm⁻³ at a first position along the first surface and increasing to a maximum value between 1×10¹⁸ cm⁻³ and about 5×10¹⁹ cm⁻³ at a second position along the first direction, the second position being separated from the first position by a distance between 1 millimeter and 25 millimeters.

7. The free-standing crystal of claim 1, wherein a crystallographic orientation of the first surface is within 10 degrees of (000±1).

8. The free-standing crystal of claim 1, wherein the thickness of each of the at least four sets of bands in the growth direction is between about 1 micrometer and about 250 micrometers.

9. The free-standing crystal of claim 1, wherein the thickness of each of the at least four sets of bands in the growth direction is between about 2 micrometers and about 100 micrometers.

10. The free-standing crystal of claim 1, wherein the at least four sets of bands comprises at least 10 sets of bands.

11. The free-standing crystal of claim 1, wherein each set of bands includes a first sub-band and a second sub-band, the first sub-band having a concentration of at least one impurity selected from H, O, Li, Na, K, F, Cl, Br, and I that is higher, by a factor between about 1.1 and about 5, than a concentration of the same impurity within the second sub-band.

12. A method for forming a group III metal nitride boule or wafer, comprising:
forming a single crystalline layer at least one millimeter thick on a surface of at least one seed crystal, wherein forming the single crystalline layer comprises:
heating a sealable container to a temperature above about 200 degrees Celsius, wherein
an interior region of the sealable container comprises the at least one seed crystal, a polycrystalline group III metal nitride nutrient material, a mineralizer material, and ammonia,
a first region of the interior region comprises the polycrystalline group III metal nitride nutrient,
a second region of the interior region comprises the at least one seed crystal, and
the heating of the sealable container causes a pressure within interior region of the sealable container to be above about 50 megapascals; and
sequentially adjusting a temperature difference between the first region and the second region, wherein
the temperature difference has a magnitude between about 1 degree Celsius and about 100 degrees Celsius and a positive or a negative sign, and
the magnitude and/or sign of the sequentially adjusted temperature difference is performed at least once during the formation of the single crystalline layer.

13. The method of claim 12, wherein the thickness of the formed single crystal layer is measured in a first growth direction, and at least 50% of dislocations formed in the formed single crystal layer have an orientation within 30 degrees of the first growth direction.

14. The method of claim 12, wherein the thickness of the formed single crystal layer is measured in a first growth direction and the formed single crystal layer comprises an oxygen gradient that decreases in the first growth direction extending from the surface of the at least one seed crystal.

15. The method of claim 12, wherein forming the single crystalline layer further comprises:
sequentially depositing a plurality of sub-bands at a material efficiency greater than 60%, wherein material efficiency is defined as a weight gain of group III metal nitride material deposited on the at least one seed crystal divided by a weight gain of group III metal material deposited on all surfaces within the second region.

16. The method of claim 15, wherein the single crystalline layer is at least 3 millimeters thick and the material efficiency is greater than 75%.

17. The method of claim 15, wherein the single crystalline layer is at least 4 millimeters thick and the material efficiency is greater than 90%.

18. The method of claim 12, wherein the sequentially adjusting the temperature difference between the first region and the second region further comprises periodically cooling and then re-heating at least one surface within the second region.

19. The method of claim 12, wherein the sequentially adjusting the temperature difference between the first region and the second region further comprises periodically heating and then re-cooling at least one surface within the first region.

20. The method of claim 12, wherein the sequentially adjusting the temperature difference between the first region and the second region further comprises at least one of
periodically cooling and then re-heating at least one surface within a first azimuthal sector of the second region and at least one surface within a second azimuthal sector of the second region, or
periodically heating and then re-cooling at least one surface within a first azimuthal sector of the first region and at least one surface within a second azimuthal sector of the first region,
wherein a time lag is present between the heating and re-cooling processes between the first azimuthal sector and the second azimuthal sector.
